(19) United States
(12) Patent Application Publication
(10) Pub. No.: US 2023/0157044 A1
(43) Pub. Date: May 18, 2023

(54) METHOD FOR PRODUCING DISPLAY DEVICE, AND DISPLAY DEVICE

(71) Applicant: SHARP KABUSHIKI KAISHA, Sakai City, Osaka (JP)

(72) Inventors: JUN SAKUMA, Sakai City, Osaka (JP); YASUSHI ASAOKA, Sakai City, Osaka (JP)

(21) Appl. No.: 17/912,497

(22) PCT Filed: Mar. 27, 2020
(86) PCT No.: PCT/JP2020/014089

§ 371 Date: Sep. 17, 2022

(51) Int. Cl. H10K 50/115; H10K 50/16; H10K 59/35

(52) U.S. Cl. CPC H10K 50/115; H10K 50/166; H10K 59/35; H10K 59/122

(57) ABSTRACT

A method for manufacturing a display device, including: a step of applying a first mixture obtained by mixing green quantum dots and a photosensitive resin on a green electron transport layer, an exposure step of pattern-exposing the first mixture to cure a portion of the first mixture, the portion being a green light-emitting layer; a development step of removing an uncured portion of the first mixture and developing the green light-emitting layer; and an etching step of etching the green electron transport layer with an etching solution that is an alkaline solution or an organic solvent using the green light-emitting layer as a mask.

### TECHNICAL FIELD

The disclosure relates to a method for manufacturing a display device and a display device.

### BACKGROUND ART

In recent years, a variety of flat panel displays have been developed, and in particular, a display device which includes a quantum dot light-emitting diode (QLED) or an organic light-emitting diode (OLED) as an electroluminescent element has attracted attention.

PTL 1 relates to a method of patterning an organic compound layer including a light-emitting layer by etching the organic compound layer using a patterned photosensitive resin layer as a mask.

PTL 2 relates to a method of patterning a light-emitting layer including quantum dots by forming the light-emitting layer using a patterned photosensitive resin as a template.

### CITATION LIST

### Patent Literature

PTL 1: JP 2014-120218 A (published on Jun. 30, 2014)
PTL 2: JP 2009-87760 A (published on Apr. 23, 2009)

### SUMMARY

### Technical Problem

However, in the known technique as described above, there is a problem in that the number of steps is large because the patterned photosensitive resin not included in the finished product is formed and removed.

In light of the above problem, an object of the disclosure is to reduce the number of steps in manufacturing a display device.

### Solution to Problem

In order to solve the above problems, a method for manufacturing a display device according to one aspect of the disclosure is a method for manufacturing the display device including a substrate, a first subpixel including a first pixel electrode provided on the substrate, a first light-emitting layer including first quantum dots, and a first charge transport layer provided between the first pixel electrode and the first light-emitting layer, and a second subpixel including a second pixel electrode provided on the substrate, the method including: forming the first charge transport layer on the first pixel electrode and the second pixel electrode; applying a first mixture obtained by mixing the first quantum dots and a photosensitive resin on the first charge transport layer; pattern-exposing the first mixture to cure a portion of the first mixture to be formed into the first light-emitting layer; removing an uncured portion of the first mixture; and etching the first charge transport layer with an etching solution using the first light-emitting layer as a mask, the etching solution being an alkaline solution or an organic solvent.

In order to solve the problem described above, a display device according to one aspect of the disclosure has a configuration including: a substrate; a first subpixel including a first pixel electrode provided on the substrate, a first light-emitting layer including first quantum dots, and a first charge transport layer provided between the first pixel electrode and the first light-emitting layer; a second subpixel including a second pixel electrode provided on the substrate, a second light-emitting layer including second quantum dots, and a second charge transport layer provided between the second pixel electrode and the second light-emitting layer and having the same polarity as the first charge transport layer, the second subpixel being adjacent to the first subpixel; and a third subpixel including a third pixel electrode provided on the substrate, a third light-emitting layer including third quantum dots, and a third charge transport layer provided between the third pixel electrode and the third light-emitting layer and having the same polarity as the first charge transport layer, the third subpixel being adjacent to the first subpixel, in which the first charge transport layer, the second charge transport layer, and the third charge transport layer are soluble in an etching solution that is an alkaline solution or an organic solvent, the first light-emitting layer is in direct contact with the first charge transport layer, the second light-emitting layer is in direct contact with the second charge transport layer, the third light-emitting layer is in direct contact with the third charge transport layer, each of the first light-emitting layer, the second light-emitting layer, and the third light-emitting layer includes a cured photosensitive resin that is insoluble in the etching solution, and the first charge transport layer, the second charge transport layer, and the third charge transport layer are separated from each other.

In order to solve the problem described above, a display device according to one aspect of the disclosure has a configuration including: a substrate; a first subpixel including a first pixel electrode provided on the substrate, a first light-emitting layer including first quantum dots, and a first charge transport layer provided between the first pixel electrode and the first light-emitting layer; a second subpixel including a second pixel electrode provided on the substrate, a second light-emitting layer including second quantum dots, and a second charge transport layer provided between the second pixel electrode and the second light-emitting layer and having the same polarity as the first charge transport layer, the second subpixel being adjacent to the first subpixel; and a third subpixel including a third pixel electrode provided on the substrate, a third light-emitting layer including third quantum dots, and a third charge transport layer provided between the third pixel electrode and the third light-emitting layer and having the same polarity as the first charge transport layer, the third subpixel being adjacent to the first subpixel, in which the first charge transport layer, the second charge transport layer, and the third charge transport layer are soluble in an etching solution that is an alkaline solution or an organic solvent, the first light-emitting layer is in direct contact with the first charge transport layer, the second light-emitting layer is in direct contact with the second charge transport layer, the third light-emitting layer is in direct contact with the third charge transport layer, each of the first light-emitting layer, the second light-emitting layer, and the third light-emitting layer includes a cured photosensitive resin that is insoluble in the etching solution, a portion of the second charge transport layer overlaps with a portion of the first charge transport layer with the first light-emitting layer interposed therebetween, and a portion of the third charge transport layer overlaps with a portion of the first charge transport layer with the first light-emitting layer interposed therebetween.

In order to solve the above problems, a display device according to one aspect of the disclosure has a configuration including: a substrate; a first subpixel including a first pixel electrode provided on the substrate, a first light-emitting layer including first quantum dots, and a first portion of a charge transport layer provided between the first pixel electrode and the first light-emitting layer; a second subpixel including a second pixel electrode provided on the substrate, a second light-emitting layer including second quantum dots, and a second portion of the charge transport layer provided between the second pixel electrode and the second light-emitting layer, the second subpixel being adjacent to the first subpixel; and a third subpixel including a third pixel electrode provided on the substrate, a third light-emitting layer including third quantum dots, and a third portion of the charge transport layer provided between the third pixel electrode and the third light-emitting layer, the third subpixel being adjacent to the first subpixel, in which the charge transport layer is soluble in an etching solution that is an alkaline solution or an organic solvent, the first light-emitting layer is in direct contact with the first portion of the charge transport layer and includes a cured photosensitive resin that is insoluble in the etching solution, and each of the second and third portions of the charge transport layer is thinner than the first portion of the charge transport layer.

### Advantageous Effects of Disclosure

According to the method for manufacturing a display device and the display device of an aspect of the disclosure, the number of steps in manufacturing a display device can be reduced.

### BRIEF DESCRIPTION OF DRAWINGS

FIG. 1 is a flowchart illustrating an example of a manufacturing method for a display device.

FIG. 2 is a cross-sectional view illustrating an example of a configuration of a display region of the display device.

FIG. 3 is a cross-sectional view illustrating a schematic configuration of an active layer in a display device according to a first embodiment of the disclosure.

FIG. 4 is a flowchart illustrating an example of a process for forming a light-emitting element layer illustrated in FIG. 3.

FIG. 5 is a schematic cross-sectional view illustrating a portion of an example of the process for forming the light-emitting element layer illustrated in FIG. 3.

FIG. 6 is a schematic cross-sectional view illustrating a portion of an example of the process for forming the light-emitting element layer illustrated in FIG. 3.

FIG. 7 is a schematic cross-sectional view illustrating a portion of an example of the process for forming the light-emitting element layer illustrated in FIG. 3.

FIG. 8 is a schematic cross-sectional view illustrating a portion of an example of the process for forming the light-emitting element layer illustrated in FIG. 3.

FIG. 9 is a schematic cross-sectional view illustrating a portion of an example of the process for forming the light-emitting element layer illustrated in FIG. 3.

FIG. 10 is a schematic cross-sectional view illustrating a portion of an example of the process for forming the light-emitting element layer illustrated in FIG. 3.

FIG. 11 is a schematic cross-sectional view illustrating a portion of an example of the process for forming the light-emitting element layer illustrated in FIG. 3.

FIG. 12 is a schematic cross-sectional view illustrating a portion of an example of the process for forming the light-emitting element layer illustrated in FIG. 3.

FIG. 13 is a schematic cross-sectional view illustrating a portion of an example of the process for forming the light-emitting element layer illustrated in FIG. 3.

FIG. 14 is a schematic cross-sectional view illustrating a portion of an example of the process for forming the light-emitting element layer illustrated in FIG. 3.

FIG. 15 is a schematic cross-sectional view illustrating a portion of an example of the process for forming the light-emitting element layer illustrated in FIG. 3.

FIG. 16 is a schematic cross-sectional view illustrating a portion of an example of the process for forming the light-emitting element layer illustrated in FIG. 3.

FIG. 17 is a schematic cross-sectional view illustrating a portion of an example of the process for forming the light-emitting element layer illustrated in FIG. 3.

FIG. 18 is a schematic cross-sectional view illustrating a portion of an example of the process for forming the light-emitting element layer illustrated in FIG. 3.

FIG. 19 is a partially enlarged view illustrating a schematic configuration of a portion indicated by a box A in FIG. 7.

FIG. 20 is a partially enlarged view illustrating a schematic configuration of a portion indicated by a box A in FIG. 8.

FIG. 21 is a partially enlarged view illustrating a schematic configuration of a portion indicated by a box A in FIG. 9.

FIG. 22 is a partially enlarged view illustrating a schematic configuration of a portion indicated by a box A in FIG. 11.

FIG. 23 is a partially enlarged view illustrating a schematic configuration of a portion indicated by a box A in FIG. 12.

FIG. 24 is a partially enlarged view illustrating a schematic configuration of a portion indicated by a box Ain FIG. 13.

FIG. 25 is a partially enlarged view illustrating a schematic configuration of a portion indicated by a box B in FIG. 15.

FIG. 26 is a partially enlarged view illustrating a schematic configuration of a portion indicated by a box B in FIG. 16.

FIG. 27 is a partially enlarged view illustrating a schematic configuration of a portion indicated by a box B in FIG. 17.

FIG. 28 is a schematic cross-sectional view illustrating a portion of a process for forming a green light-emitting layer according to Comparative Example.

FIG. 29 is a schematic cross-sectional view illustrating a portion of the process for forming the green light-emitting layer according to Comparative Example.

FIG. 30 is a schematic cross-sectional view illustrating a portion of a process for forming a blue light-emitting layer according to Comparative Example.

FIG. 31 is a schematic cross-sectional view illustrating a portion of the process for forming the blue light-emitting layer according to Comparative Example.

FIG. 32 is a cross-sectional view illustrating a schematic configuration of a light-emitting element layer in a display device according to a modified example of the first embodiment of the disclosure.

FIG. 33 is a schematic cross-sectional view illustrating a portion of an example of a process for forming the light-emitting element layer illustrated in FIG. 32.

FIG. 34 is a cross-sectional view illustrating a schematic configuration of an active layer in a display device according to a second embodiment of the disclosure.

FIG. 35 is a schematic cross-sectional view illustrating a portion of an example of a process for forming the light-emitting element layer illustrated in FIG. 34.

FIG. 36 is a schematic cross-sectional view illustrating a portion of an example of the process for forming the light-emitting element layer illustrated in FIG. 34.

FIG. 37 is a cross-sectional view illustrating a schematic configuration of an active layer in a display device according to a third embodiment of the disclosure.

FIG. 38 is a cross-sectional view illustrating a schematic configuration of an active layer in a display device according to a fourth embodiment of the disclosure.

FIG. 39 is a cross-sectional view illustrating a schematic configuration of an active layer in a display device according to a fifth embodiment of the disclosure.

FIG. 40 is a flowchart illustrating an example of a process for forming the light-emitting element layer illustrated in FIG. 39.

FIG. 41 is a schematic cross-sectional view illustrating a portion of an example of the process for forming the light-emitting element layer illustrated in FIG. 39.

FIG. 42 is a schematic cross-sectional view illustrating a portion of an example of the process for forming the light-emitting element layer illustrated in FIG. 39.

FIG. 43 is a schematic cross-sectional view illustrating a portion of an example of the process for forming the light-emitting element layer illustrated in FIG. 39.

FIG. 44 is a schematic cross-sectional view illustrating a portion of an example of the process for forming the light-emitting element layer illustrated in FIG. 39.

FIG. 45 is a schematic cross-sectional view illustrating a portion of an example of the process for forming the light-emitting element layer illustrated in FIG. 39.

FIG. 46 is a schematic cross-sectional view illustrating a portion of an example of the process for forming the light-emitting element layer illustrated in FIG. 39.

FIG. 47 is a schematic cross-sectional view illustrating a portion of an example of the process for forming the light-emitting element layer illustrated in FIG. 39.

FIG. 48 is a cross-sectional view illustrating a schematic configuration of an active layer in a display device according to a sixth embodiment of the disclosure.

FIG. 49 is a flowchart illustrating an example of a process for forming a light-emitting element layer illustrated in FIG. 48.

FIG. 50 is a schematic cross-sectional view illustrating a portion of an example of the process for forming the light-emitting element layer illustrated in FIG. 48.

FIG. 51 is a schematic cross-sectional view illustrating a portion of an example of the process for forming the light-emitting element layer illustrated in FIG. 48.

FIG. 52 is a cross-sectional view illustrating a schematic configuration of an active layer in a display device according to a seventh embodiment of the disclosure.

FIG. 53 is a cross-sectional view illustrating a schematic configuration of an active layer in a display device according to an eighth embodiment of the disclosure.

FIG. 54 is a flowchart illustrating an example of a process for forming a light-emitting element layer illustrated in FIG. 53.

FIG. 55 is a cross-sectional view illustrating a schematic configuration of an active layer in a display device according to a ninth embodiment of the disclosure.

FIG. 56 is a cross-sectional view illustrating a schematic configuration of an active layer in a display device according to a tenth embodiment of the disclosure.

FIG. 57 is a plan view illustrating an example of an arrangement pattern of green pixel electrodes, blue pixel electrodes, and red pixel electrodes.

FIG. 58 is a plan view illustrating an example of a forming pattern of a green light-emitting layer illustrated in FIG. 56 in a case where pixel electrodes are in the arrangement pattern illustrated in FIG. 57.

FIG. 59 is a plan view illustrating an example of a forming pattern of a blue light-emitting layer illustrated in FIG. 56 in a case where pixel electrodes are in the arrangement pattern illustrated in FIG. 57.

FIG. 60 is a plan view illustrating an example of a forming pattern of a red light-emitting layer illustrated in FIG. 56 in a case where pixel electrodes are in the arrangement pattern illustrated in FIG. 57.

FIG. 61 is a cross-sectional view illustrating a schematic configuration of an active layer in a display device according to an eleventh embodiment of the disclosure.

FIG. 62 is a cross-sectional view illustrating a schematic configuration of an active layer in a display device according to a twelfth embodiment of the disclosure.

### DESCRIPTION OF EMBODIMENTS

### Method for Manufacturing Display Device and Configuration

In the following description, the “same layer” means that it is formed through the same process (film formation step), the “lower layer” means that it is formed through a process before that of the compared layer, and the “upper layer” means that it is formed through a process after that of the compared layer.

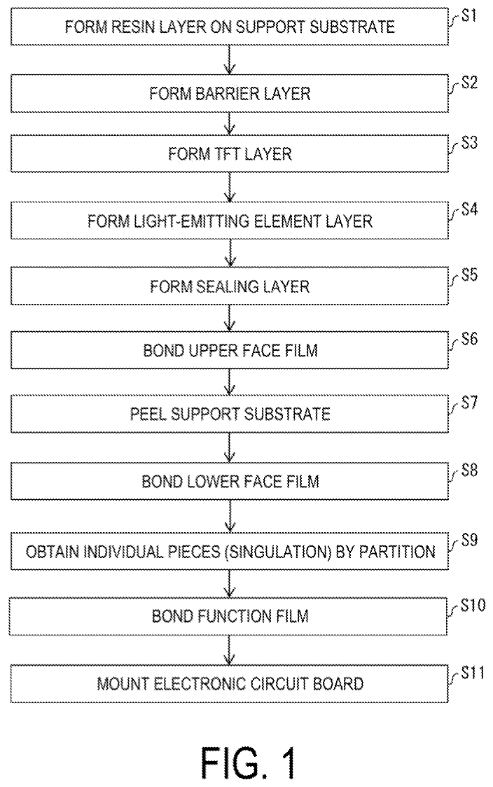

FIG. 1 is a flowchart illustrating an example of a method for manufacturing a display device. FIG. 2 is a schematic cross-sectional view illustrating an example of a configuration of a display region of a display device 2.

In a case where a flexible display device is manufactured, as illustrated in FIG. 1 and FIG. 2, first, a resin layer 12 is formed on a light-transmissive support substrate (a mother glass, for example) (step S1). Next, a barrier layer 3 is formed (step S2). Next, a thin film transistor layer (TFT layer) 4 is formed (step S3). Next, a top-emitting type light-emitting element layer 5 is formed (step S4). Next, a sealing layer 6 is formed (step S5). Next, an upper face film is bonded on the sealing layer 6 (step S6).

Next, the support substrate is peeled from the resin layer 12 due to irradiation with a laser light or the like (step S7). Next, a lower face film 10 is bonded to the lower face of the resin layer 12 (step S8). Next, a layered body including the lower face film 10, the resin layer 12, the barrier layer 3, the thin film transistor layer 4, the light-emitting element layer 5, and the sealing layer 6 is divided to obtain a plurality of individual pieces (step S9). Next, a function film 39 is bonded to the obtained individual pieces (step S10). Next, an electronic circuit board (for example, an IC chip or an FPC) is mounted on a portion (terminal portion) of the display region located further outward (a non-display region or a frame region) than a portion where a plurality of subpixels are formed (step S11). Note that steps S1 to S11 are executed by a display device manufacturing apparatus (including a film formation apparatus that executes the process from steps S1 to S5).

Examples of the material of the resin layer 12 include polyimide and the like. A portion of the resin layer 12 can be replaced by two resin films (for example, polyimide films) with an inorganic insulating film sandwiched therebetween.

The barrier layer 3 is a layer that inhibits foreign matter such as water and oxygen from entering the thin film transistor layer 4 and the light-emitting element layer 5. For example, the barrier layer can be constituted of a silicon oxide film, a silicon nitride film, or a silicon oxynitride film, or a layered film thereof formed by chemical vapor deposition (CVD).

The thin film transistor layer 4 includes a semiconductor film 15, an inorganic insulating film 16 (gate insulating film) which is an upper layer above the semiconductor film 15, a gate electrode GE and a gate wiring line GH1 which are upper layers above the inorganic insulating film 16, an inorganic insulating film 18 (interlayer insulating film) which is an upper layer above the gate electrode GE and the gate wiring line GH, a capacitance electrode CE which is an upper layer above the inorganic insulating film 18, an inorganic insulating film 20 (interlayer insulating film) which is an upper layer above the capacitance electrode CE, a source wiring line SH which is an upper layer above the inorganic insulating film 20, and a flattening film 21 (interlayer insulating film) which is an upper layer above the source wiring line SH.

The semiconductor film 15 is formed of low-temperature polysilicon (LTPS) or an oxide semiconductor (for example, an In—Ga—Zn—O based semiconductor), for example. FIG. 2 illustrates the transistor that has a top gate structure, but the transistor may have a bottom gate structure.

The gate electrode GE, the gate wiring line GH, the capacitance electrode CE, and the source wiring line SH are each composed of a single layer film or a layered film of a metal, for example. including at least one of aluminum, tungsten, molybdenum, tantalum, chromium, titanium, and copper.

The inorganic insulating films 16, 18, and 20 may be composed of, for example, a silicon oxide (SiOx) film, a silicon nitride (SiNx) film, or a silicon oxynitride (SiNO), or of a layered film of these, formed by a CVD method. The flattening film 21 may be composed of coatable organic materials such as polyimide and acrylic.

The light-emitting element layer 5 includes a cathode 25 (cathode electrode, so-called pixel electrode) which is an upper layer above the flattening film 21, an edge cover 23 having insulating properties and covering an edge of the cathode 25, an active layer 24 which is an upper layer above the edge cover 23, the active layer 24 being an electroluminescent (EL) layer, and an anode 22 (anode electrode, so-called common electrode) which is an upper layer above the active layer 24. The edge cover 23 is formed by applying an organic material such as a polyimide or an acrylic and then patterning the organic material by photolithography, for example.

For each subpixel, a light-emitting element ES (electroluminescent element) including the cathode 25 having an island shape, the active layer 24, and the anode 25 and being a QLED is formed in the light-emitting element layer 5, and a subpixel circuit for controlling the light-emitting element ES is formed in the thin film transistor layer 4.

For example, the active layer 24 is formed by layering an electron injection layer, an electron transport layer, a light-emitting layer, a hole transport layer, and a hole injection layer in this order, from the lower layer side. It is also possible to adopt a configuration in which one or more of the electron injection layer, electron transport layer, hole transport layer, and hole injection layer are not formed.

The cathode 25 is a reflective electrode which is formed by layering, for example, indium tin oxide (ITO) and silver (Ag) or an alloy containing Ag, or formed from a material including Ag or Al and has light reflectivity. The anode 22 is a transparent electrode which is constituted of a thin film of Ag, Au, Pt, Ni, or Ir, a thin film of a MgAg alloy, or a light-transmissive conductive material such as ITO, or indium zinc oxide (IZO). When the display device is not a top-emitting type display device but is a bottom-emitting type display device, the lower face film 10 and the resin layer 12 are light-transmissive, the cathode 25 is a transparent electrode, and the anode 22 is a reflective electrode.

Alternatively, it is also possible to adopt a configuration in which the anode 22 having an island shape is formed as a so-called pixel electrode in an upper layer above the flattening film 21, and the cathode 25 is formed as a so-called common electrode in an upper layer above the active layer 24. In this case, for example, the active layer 24 is formed by layering a hole injection layer, a hole transport layer, a light-emitting layer, an electron transport layer, and an electron injection layer in this order, from the lower layer side. It is also possible to adopt a configuration in which one or more of the hole injection layer, hole transport layer, electron transport layer, and electron injection layer are not formed. In addition, when the display device is a top-emitting type display device, the cathode 25 is a transparent electrode and the anode 22 is a reflective electrode, while when the display device is a bottom-emitting type display device, the anode 22 is a transparent electrode and the cathode 25 is a reflective electrode.

In the light-emitting element ES, positive holes and electrons recombine inside the light-emitting layer in response to a drive current between the anode 22 and the cathode 25, and when excitons generated due to this recombination transition from the lowest unoccupied molecular orbital (LUMO) or the conduction band to the highest occupied molecular orbital (HOMO) or the valence band of the quantum dots, light is emitted.

The sealing layer 6 is light-transmissive, and includes an inorganic sealing film 26 for covering the anode 25, an organic buffer film 27 which is an upper layer above the inorganic sealing film 26, and an inorganic sealing film 28 which is an upper layer above the organic buffer film 27. The sealing layer 6 covering the light-emitting element layer 5 inhibits foreign matters such as water and oxygen from penetrating the light-emitting element layer 5.

Each of the inorganic sealing film 26 and the inorganic sealing film 28 is an inorganic insulating film and can be formed of, for example, a silicon oxide film, a silicon nitride film, or a silicon oxynitride film, or a layered film of these, formed by CVD. The organic buffer film 27 is a transparent organic film having a flattening effect and can be formed of a coatable organic material such as an acrylic. The organic buffer film 27 can be formed, for example, by ink-jet application, and a bank for stopping droplets may be provided in a non-display region.

The lower face film 10 is, for example, a PET film bonded in a lower face of the resin layer 12 after the support substrate is peeled, to realize a display device having excellent flexibility. The function film 39 has at least one of an optical compensation function, a touch sensor function, and a protection function, for example.

The flexible display device has been described above, but when manufacturing the display device as a non-flexible display device, because typical formation of the resin layer and replacement of the substrate are not required, the process proceeds to step S9 after the layering process on the glass substrate of steps S2 to S5 is executed. Furthermore, when a non-flexible display device is manufactured, a light-transmissive sealing member may be caused to adhere using a sealing adhesive instead of or in addition to forming the sealing layer 6, under a nitrogen atmosphere. The light-transmissive sealing member can be formed from glass, plastic, or the like, and preferably has a concave shape.

One embodiment of the disclosure particularly relates to step S4 of the method for manufacturing a display device described above.

### First Embodiment

Hereinafter, an embodiment of the disclosure will be described in detail with reference to the drawings. However, shapes, dimensions, relative arrangements, and the like illustrated in the drawings are merely exemplary, and the scope of the disclosure should not be construed as limiting due to these.

As illustrated in FIG. 2, a display device 2 according to a first embodiment of the disclosure includes a lower face film 10, a resin layer 12, a barrier layer 3, and a thin film transistor layer 4, and a light-emitting element layer 5 is further formed on the substrate. Hereinafter, for convenience, a structure composed of the lower face film 10 (or support substrate), the resin layer 12, the barrier layer 3, and the thin film transistor layer 4 will be sometimes referred to as a “substrate”.

### Configuration of Light-Emitting Element Layer

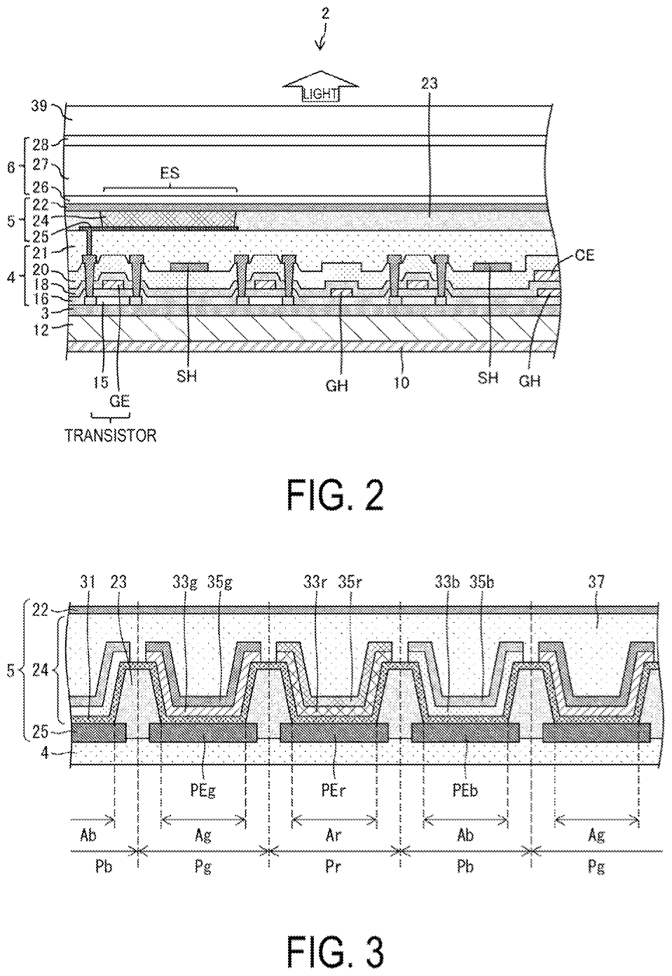

FIG. 3 is a cross-sectional view illustrating a schematic configuration of the light-emitting element layer 5 in the display device 2 according to the first embodiment of the disclosure.

As illustrated in FIG. 3, the display device 2 according to the first embodiment of the disclosure includes a green subpixel Pg (first subpixel) including a green pixel electrode PEg (first pixel electrode) provided on the substrate, a blue subpixel Pb (second subpixel) including a blue pixel electrode PEb (second pixel electrode) provided on the substrate, and a red subpixel Pr (third subpixel) including a red pixel electrode PEr (third pixel electrode) provided on the substrate.

The light-emitting element layer 5 according to the first embodiment of the disclosure includes a cathode 25 in an upper layer above the thin film transistor layer 4 as the green pixel electrode PEg, the blue pixel electrode PEb, and the red pixel electrode PEr. The light-emitting element layer 5 includes an edge cover 23 (bank) having insulating properties and covering an edge of the cathode 25, and an active layer 24 in an upper layer above the edge cover 23, the active layer 24 being an electroluminescent (EL) layer. The light-emitting element layer 5 includes an anode 22 in an upper layer above the active layer 24 as a common electrode.

The active layer 24 includes an electron injection layer 31 formed in a solid shape (common layer). The electron injection layer 31 is formed in a solid shape so as to cover the anode 22 and the edge cover 23. This is not a limitation, and the electron injection layer 31 need not be formed, or may be formed in an island shape so as to individually cover the anode 22.

The active layer 24 includes a green electron transport layer 33g (first charge transport layer) formed in an island shape and a green light-emitting layer 35g (first light-emitting layer) formed in an island shape, in the green subpixel Pg.

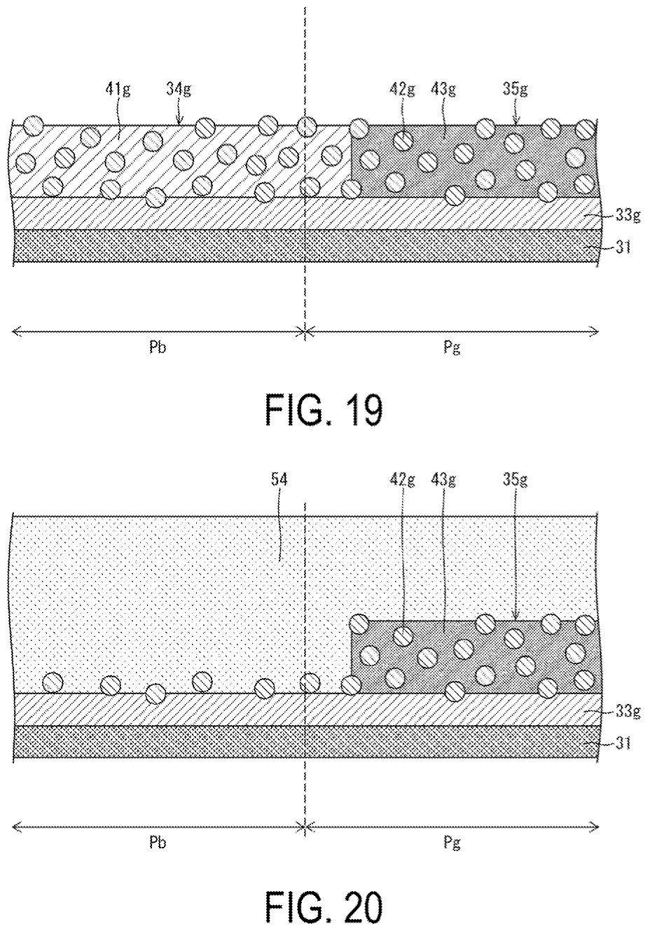

The green light-emitting layer 35g includes green quantum dots 42g (first quantum dots) that emit green light (see FIGS. 19 to 31) and a cured green photosensitive resin 43g (see FIGS. 19 to 31), and the green quantum dots 42g are fixed by the green photosensitive resin 43g. The green light-emitting layer 35g is in direct contact with the green electron transport layer 33g and covers the entire upper surface of the green electron transport layer 33g.

The green electron transport layer 33g is provided between the green pixel electrode PEg and the green light-emitting layer 35g. The green electron transport layer 33g is composed of an electron transport material capable of being etched using an etching solution 56 that does not erode the green light-emitting layer 35g (i.e., cured green photosensitive resin 43g). The photosensitive resin after curing is often insoluble in an alkaline solution such as a potassium hydroxide (KOH) aqueous solution, a tetramethylammonium hydroxide (TMAH) aqueous solution, a sodium carbonate (Na₂CO₃) aqueous solution, and a sodium hydrogen carbonate (NaHCO₃) aqueous solution. Thus, the etching solution 56 is preferably an alkaline solution in which the green photosensitive resin 43g is insoluble. In this case, the green electron transport layer 33g is composed of an electron transport material soluble in the alkaline solution in which the green photosensitive resin 43g is insoluble. Such an electron transport material is an oxide having, as a main composition, an amphoteric metal such as ZnO, AlZnO, LiZnO, or MgZnO, for example.

The active layer 24 includes a blue electron transport layer 33b (second charge transport layer) formed in an island shape, and a blue light-emitting layer 35b (second light-emitting layer) formed in an island shape, in the blue subpixel Pb.

The blue light-emitting layer 35b includes blue quantum dots 42b (second quantum dots) that emit blue light (see FIGS. 22 to 24, and FIGS. 30 to 31), and a cured blue photosensitive resin 43b (see FIGS. 22 to 24, and FIGS. 30 to 31), and the blue quantum dots 42b are fixed by the cured blue photosensitive resin 43b. The blue light-emitting layer 35b is in direct contact with the blue electron transport layer 33b and covers the entire upper surface of the blue electron transport layer 33b.

The blue electron transport layer 33b is provided between the blue pixel electrode PEb and the blue light-emitting layer 35b. The blue electron transport layer 33b is composed of an electron transport material capable of being etched using the etching solution 56 that does not erode the blue light-emitting layer 35b (i.e., the cured blue photosensitive resin 43b). The photosensitive resin after curing is often insoluble in the alkaline solution as described above. Thus, the etching solution 56 is preferably an alkaline solution in which the blue photosensitive resin 43b is insoluble. In this case, the blue electron transport layer 33b is preferably composed of an electron transport material soluble in the alkaline solution in which the blue photosensitive resin 43b is insoluble. Such an electron transport material is an oxide having, as a main composition, an amphoteric metal such as ZnO, AlZnO, LiZnO, or MgZnO, for example.

The active layer 24 includes a red electron transport layer 33r (third charge transport layer) formed in an island shape, and a red light-emitting layer 35r (third light-emitting layer) formed in an island shape, in the red subpixel Pr.

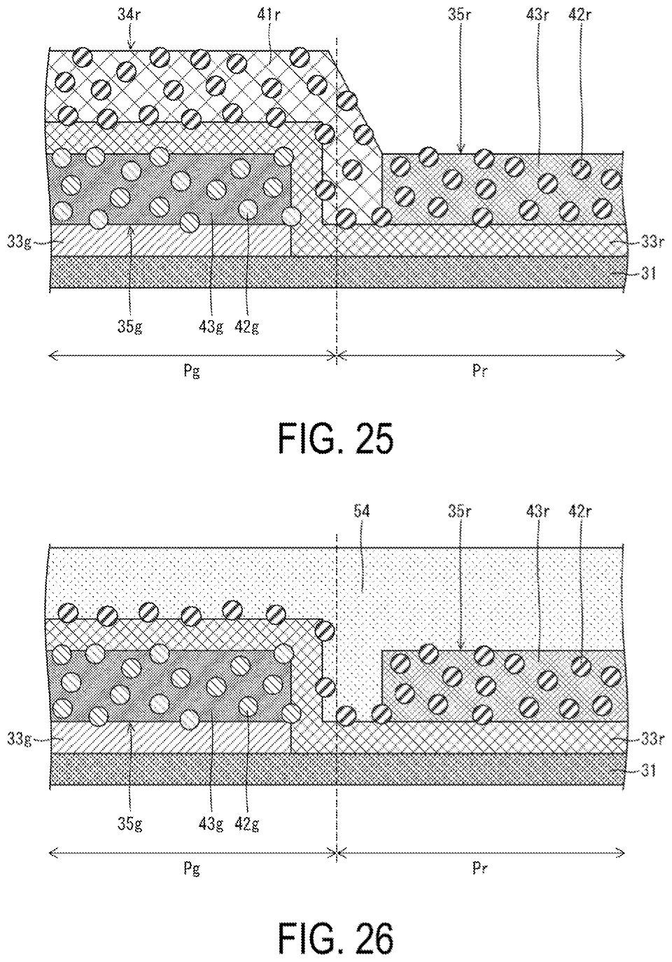

The red light-emitting layer 35r includes red quantum dots 42r (third quantum dots)(see FIGS. 25 to 28) that emits red light and a cured red photosensitive resin 43r (see FIGS. 25 to 28), and the red quantum dots 42r are fixed by the red photosensitive resin 43r. The red light-emitting layer 35r is in direct contact with the red electron transport layer 33r, and covers the entire upper surface of the red electron transport layer 33r.

The red electron transport layer 33r is provided between the red pixel electrode PEr and the red light-emitting layer 35r. The red electron transport layer 33r is composed of an electron transport material capable of being etched using the etching solution 56 that does not erode the red light-emitting layer 35r (i.e., the cured red photosensitive resin 43r). The photosensitive resin after curing is often insoluble in the alkaline solution as described above. Thus, the etching solution 56 is preferably an alkaline solution in which the red photosensitive resin 43r is insoluble. In this case, the red electron transport layer 33r is composed of an electron transport material soluble in the alkaline solution in which the red photosensitive resin 43r is insoluble. Such an electron transport material is an oxide having, as a main composition, an amphoteric metal such as ZnO, AlZnO, LiZnO, or MgZnO, for example.

The green electron transport layer 33g, the blue electron transport layer 33b, and the red electron transport layer 33r have the same polarity as each other, and are separated from each other. The green electron transport layer 33g, the blue electron transport layer 33b, and the red electron transport layer 33r may be formed of materials different from each other or the same material as each other, and may have different film thicknesses from each other or the same film thickness as each other. For example, preferably, in view of a resonance effect, the material and/or film thickness of the green electron transport layer 33g, the blue electron transport layer 33b, and the red electron transport layer 33r are selected.

The active layer 24 includes a hole transport layer 37 (fourth charge transport layer) formed in a solid shape. The hole transport layer 37 has a reverse polarity with respect to the green electron transport layer 33g, the blue electron transport layer 33b, and the red electron transport layer 33r. The hole transport layer 37, along with the anode 22, is located on the opposite side of the electron injection layer 31 with respect to each of the green light-emitting layer 35g, the blue light-emitting layer 35b, and the red light-emitting layer 35r. The hole transport layer 37 is formed in a solid shape so as to cover the green light-emitting layer 35g, the red light-emitting layer 35r, and the blue light-emitting layer 35b (and when exposed, the exposed portion of the electron injection layer 31 and the exposed portion of the edge cover 23). This is not a limitation, and the hole transport layer 37 need not be formed, or may be paired with the cathode 25 to be formed in an island shape separated for each pixel so as to individually cover the green light-emitting layer 35g, the red light-emitting layer 35r, and the blue light-emitting layer 35b. Further, the hole transport layer 37 may have a multilayer structure.

Although not illustrated in the drawings, the active layer 24 may include one or more additional electron transport layers between the electron injection layer 31 and the green electron transport layer 33g, may include one or more additional electron transport layers between the electron injection layer 31 and the red electron transport layer 33r, or may include one or more additional electron transport layers between the electron injection layer 31 and the blue electron transport layer 33b. The additional electron transport layer may be formed in an island shape separately for each of the green subpixel Pg, the red subpixel Pr, and the blue subpixel Pb, or may be formed commonly in a solid shape.

### Light-Emitting Element Layer Forming Process

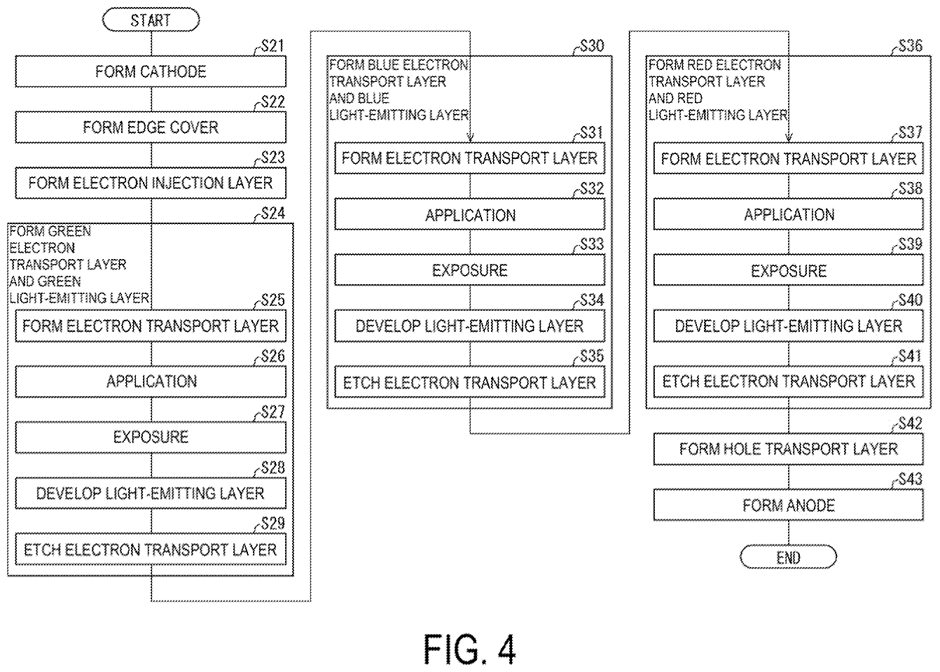

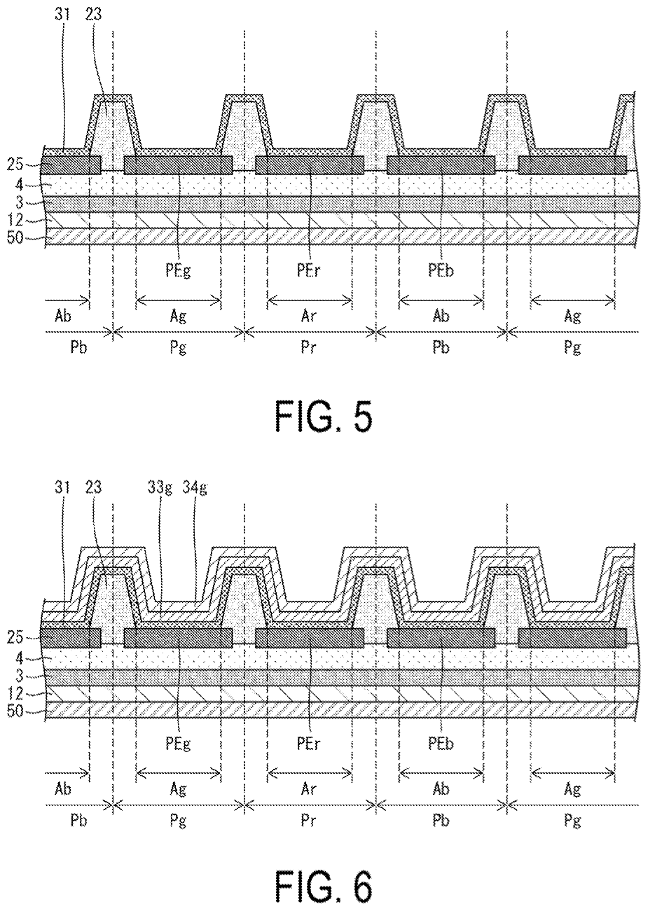

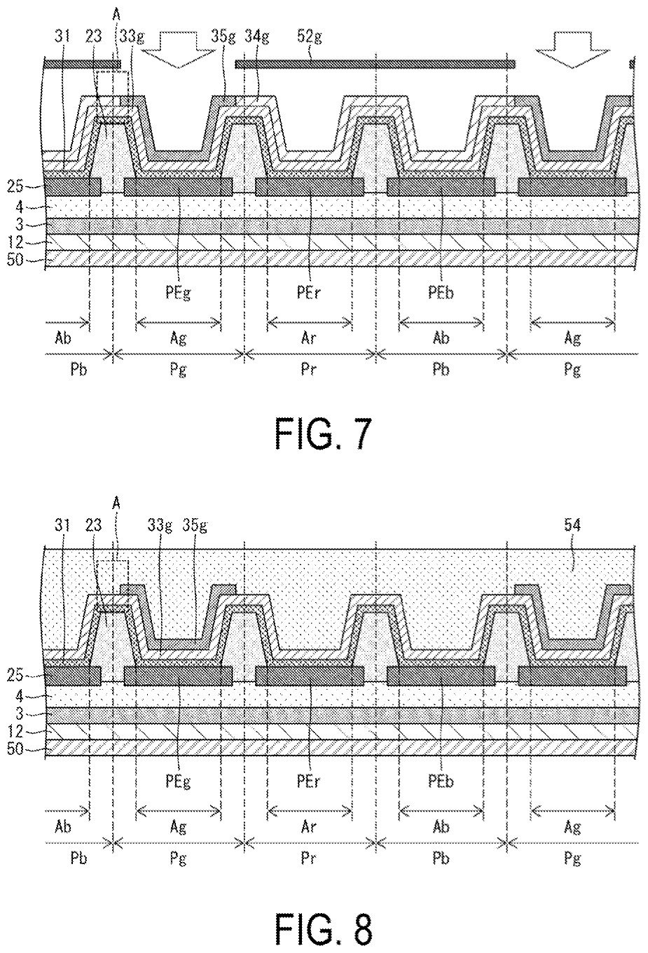

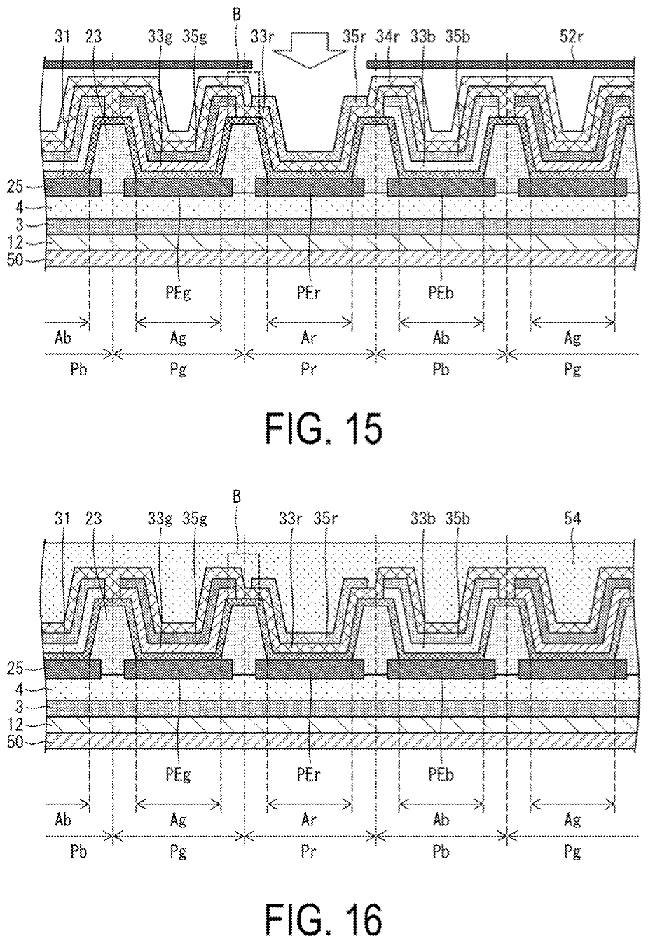

Hereinafter, with reference to FIGS. 4 to 27, a process for forming the light-emitting element layer 5 in a method for manufacturing the display device 2 according to the first embodiment of the disclosure (i.e., step S4 in FIG. 1) will be described. FIG. 4 is a flowchart illustrating an example of the process for forming the light-emitting element layer 5 illustrated in FIG. 3. FIGS. 5 to 18 are schematic cross-sectional views illustrating portions of the example of the process for forming the light-emitting element layer 5 illustrated in FIG. 3. FIGS. 19 to 24 are partially enlarged views illustrating schematic configurations of portions indicated by boxes A in FIGS. 7 to 9 and FIGS. 11 to 13, respectively. FIGS. 25 to 27 are partially enlarged views illustrating schematic configurations of the portions indicated by boxes B in FIGS. 15 to 17, respectively.

First, as illustrated in FIG. 5, the resin layer 12, the barrier layer 3, and the thin film transistor layer 4 are formed in this order on the support substrate 50.

Then, as illustrated in FIG. 4 and FIG. 5, the cathodes 25 are formed on the thin film transistor layer 4 as the green pixel electrode PEg, the red pixel electrode PEr, and the blue pixel electrode PEb (step S21). Subsequently, the edge cover 23 is formed so as to cover a perimeter edge portion of each of the cathodes 25 (step S22). Subsequently, the electron injection layer 31 is formed so as to cover the cathodes 25 (step S23).

Then, formation of the green electron transport layer 33g and the green light-emitting layer 35g (step S24), formation of the blue electron transport layer 33b and the blue light-emitting layer 35b (step S30), and formation of the red electron transport layer 33r and the red light-emitting layer 35r (step S36) are sequentially performed. Steps S24, S30, and S36 may be performed in any order. In the present specification, a case in which steps S24, S30, and S36 are performed in this order will be described as an example.

In step S24, first, as illustrated in FIG. 4 and FIG. 6, the green electron transport layer 33g is formed (first charge transport layer forming step) (step S25), and a green coating liquid 34g is applied on the green electron transport layer 33g (first mixture application step) (step S26). In step S25, the green electron transport layer 33g is formed in a solid shape over the green pixel electrode PEg and over the red pixel electrode PEr and the blue pixel electrode PEb. In step S26, the green coating liquid 34g is applied directly onto the entire green electron transport layer 33g in a solid shape. The green coating liquid 34g is a first mixture in which the green quantum dots 42g are mixed in an uncured green photosensitive resin 41g (see FIG. 19).

Subsequently, in step S24, as illustrated in FIG. 4 and FIG. 7, the green coating liquid 34g is pattern-exposed using a green photomask 52g so as to form a pattern shape in which a portion of the green coating liquid 34g to be the green light-emitting layer 35g is cured, and the other portion is not cured (first mixture exposure step) (step S27). At this time, as illustrated in FIG. 19, the green quantum dots 42g of the cured portion (i.e., the green light-emitting layer 35g) are fixed by the cured green photosensitive resin 43g. At the same time, some of the green quantum dots 42g are adsorbed and/or mixed into the green electron transport layer 33g.

Subsequently, in step S24, as illustrated in FIG. 4 and FIG. 8, the uncured portion of the green coating liquid 34g is removed by a developer 54 to develop the green light-emitting layer 35g (that is, the cured portion of the green coating liquid 34g) (first mixture removal step) (step S28). The developer 54 is an alkaline solution. In this way, the green light-emitting layer 35g is formed using a photolithography technique. At this time, as illustrated in FIG. 20, the green quantum dots 42g of the uncured portion are removed along with the uncured green photosensitive resin 41g. However, among the green quantum dots 42g of the uncured portion, a part of the green quantum dots 42g adsorbed or mixed into the green electron transport layer 33g remains in the surface and/or interior of the green electron transport layer 33g corresponding to the uncured portion without being removed.

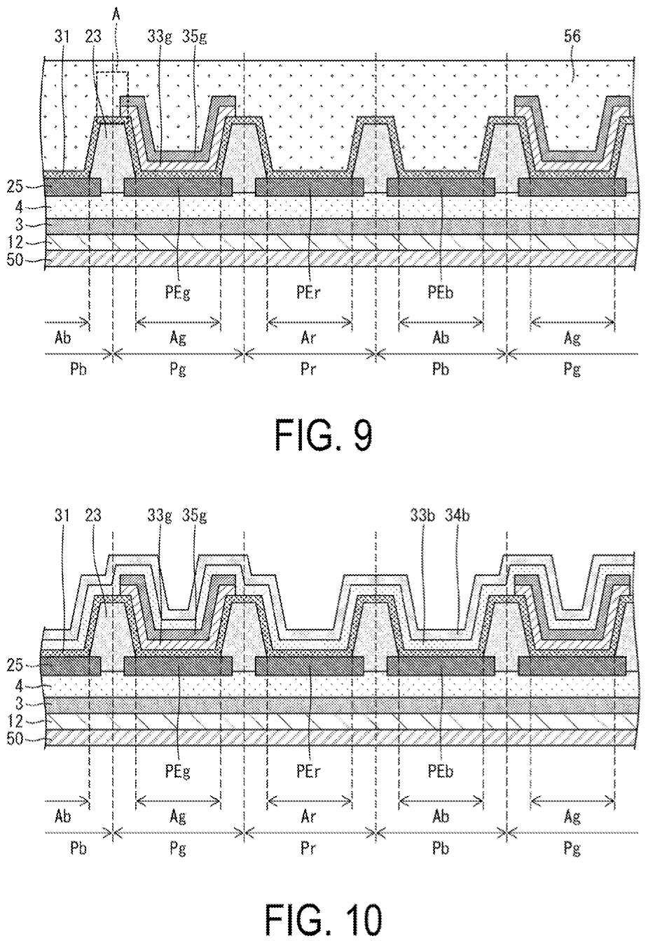

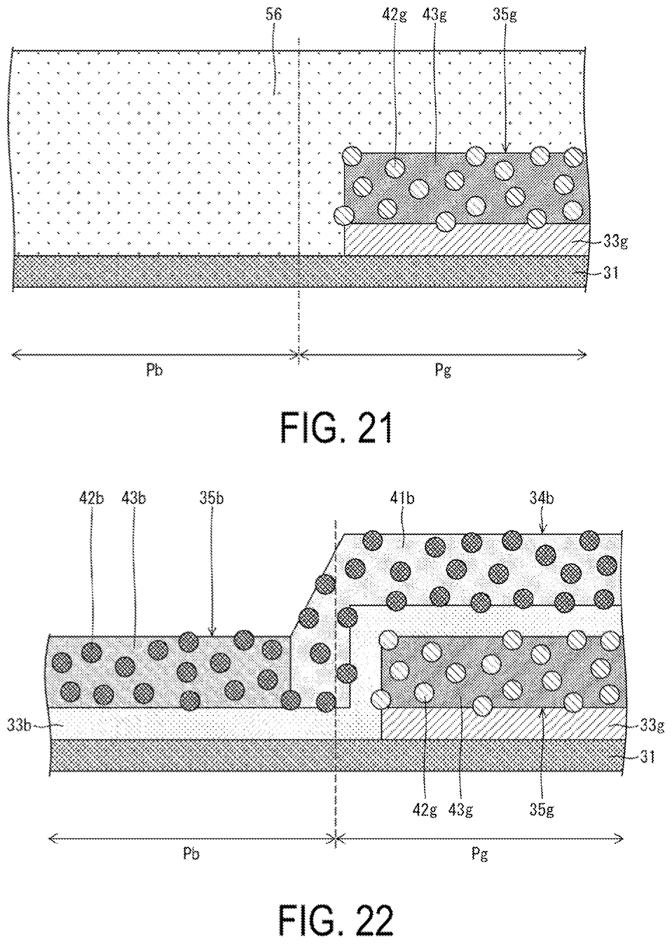

Finally, at step S24, as illustrated in FIG. 4 and FIG. 9, the green light-emitting layer 35g is used as a mask to etch the green electron transport layer 33g using the etching solution 56 (first etching step) (step S29). This removes the green electron transport layer 33g corresponding to the uncured portion of the green coating liquid 34g. At this time, as illustrated in FIG. 21, the green quantum dots 42g remaining in the green electron transport layer 33g corresponding to the uncured portion are removed along with the green electron transport layer 33g corresponding to the uncured portion. The etching solution 56 in step S29 is preferably the same alkaline solution as the developer 54 in step S28. When it is the same, steps S28 and S29 can be performed sequentially in a single step or in parallel, and thus the number of steps of the method for manufacturing the display device 2 can be further reduced. In other words, preferably, the uncured green photosensitive resin 41g is soluble in the etching solution 56, and the cured green photosensitive resin 43g is insoluble in the etching solution 56.

Note that in step S29, the green electron transport layer 33g corresponding to the green light-emitting layer 35g may be side-etched. Thus, in a plan view, the green light-emitting layer 35g is preferably formed wider than an effective light-emitting region of the green subpixel Pg, that is, an opening Ag of the edge cover 23. Furthermore, the green light-emitting layer 35g is as wide as or wider than the green electron transport layer 33g after etching in a plan view.

In subsequent step S30, first, as illustrated in FIG. 4 and FIG. 10, the blue electron transport layer 33b is formed (second charge transport layer forming step) (step S31), and a blue coating liquid 34b is applied on the blue electron transport layer 33b (second mixture application step) (step S32). In step S31, the blue electron transport layer 33b is formed in a solid shape over the blue pixel electrode PEb and over the red pixel electrode PEr and the green pixel electrode PEg. Furthermore, in step S32, the blue coating liquid 34b is applied directly on the entire blue electron transport layer 33b into a solid shape. The blue coating liquid 34b is a second mixture in which the blue quantum dots 42b are mixed into an uncured blue photosensitive resin 41b (see FIG. 22 and FIG. 30). The blue photosensitive resin 41b may be the same resin as the green photosensitive resin 41g or may be a different resin.

Subsequently, in step S30, as illustrated in FIG. 4 and FIG. 11, the blue coating liquid 34b is pattern-exposed using a blue photomask 52b so as to form a pattern shape in which a portion to be the blue light-emitting layer 35b is cured, and the other portion is not cured (second mixture exposure step) (step S33). At this time, as illustrated in FIG. 22, the blue quantum dots 42b of the cured portion (i.e., the blue light-emitting layer 35b) are fixed by the cured blue photosensitive resin 43b. At the same time, some of the blue quantum dots 42b are adsorbed and/or mixed in the blue electron transport layer 33b. On the other hand, the green light-emitting layer 35g is covered by the blue electron transport layer 33b, and thus the blue quantum dots 42b are not adsorbed or mixed in the green light-emitting layer 35g.

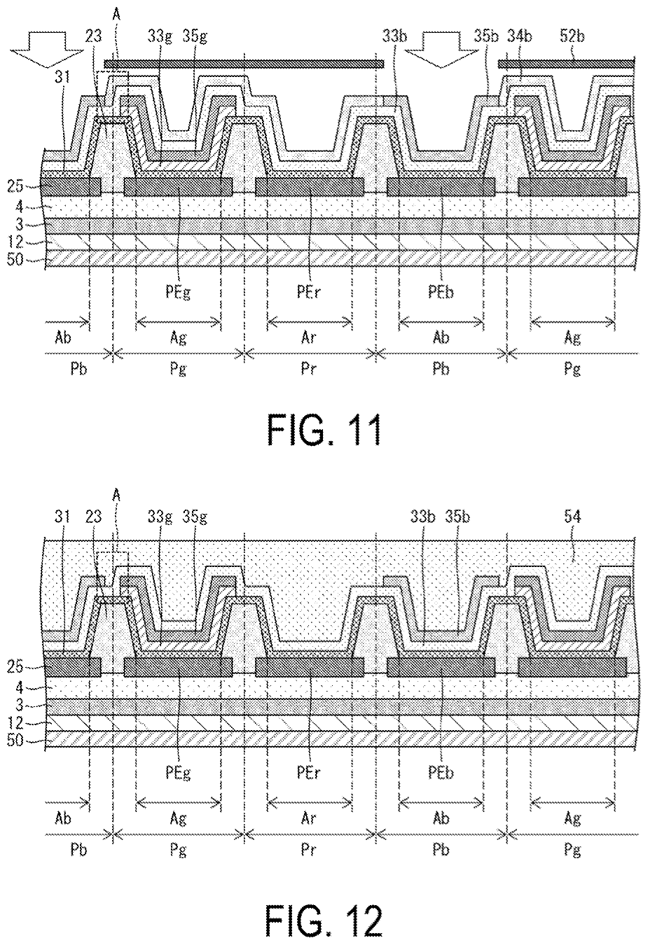

Subsequently, in step S30, as illustrated in FIG. 4 and FIG. 12, the uncured portion of the blue coating liquid 34b is removed by the developer 54 to develop the blue light-emitting layer 35b (i.e., the cured portion of the blue coating liquid 34b) (second mixture removal step) (step S34). The developer 54 is an alkaline solution. In this way, the blue light-emitting layer 35b is formed using a photolithography technique. At this time, as illustrated in FIG. 23, the blue quantum dots 42b of the uncured portion are removed along with the uncured blue photosensitive resin 41b. However, among the blue quantum dots 42b of the uncured portion, a part of the blue quantum dots 42b adsorbed or mixed in the blue electron transport layer 33b remains in the surface and/or interior of the blue electron transport layer 33b without being removed. In addition, as illustrated in FIG. 12 and FIG. 23, the green light-emitting layer 35g remains covered with the blue electron transport layer 33b.

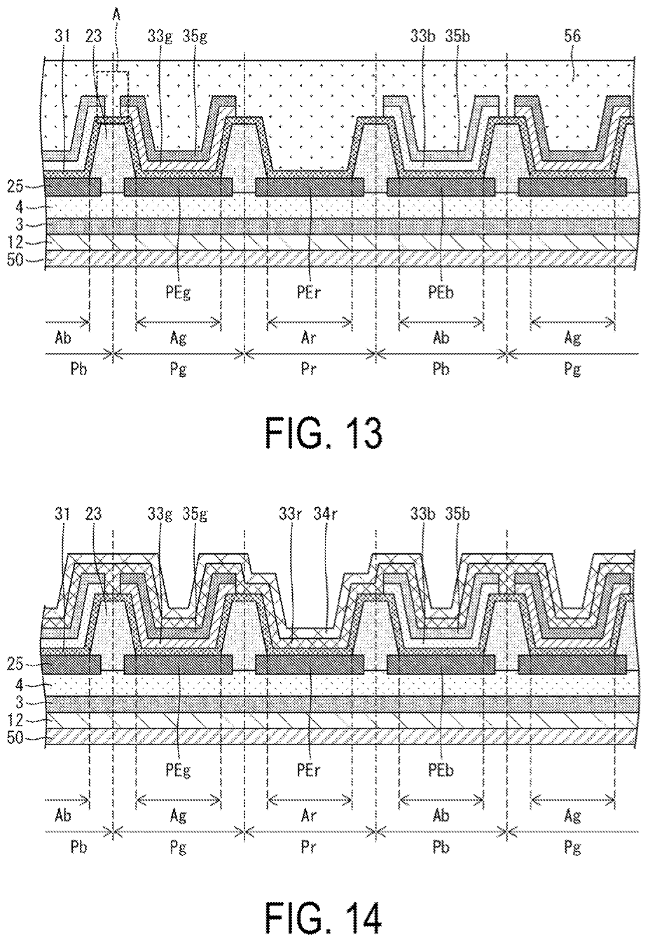

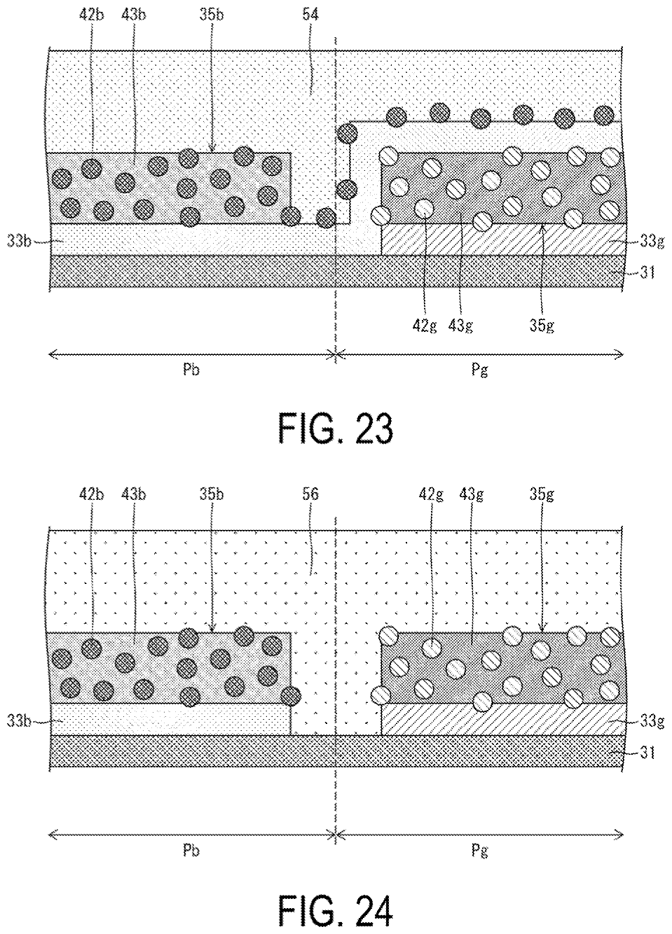

Finally, in step S30, as illustrated in FIG. 4 and FIG. 13, the blue light-emitting layer 35b is used as a mask to etch the blue electron transport layer 33b using the etching solution 56 (second etching step) (step S35). This removes the blue electron transport layer 33b corresponding to the uncured portion of the blue coating liquid 34b. At this time, as illustrated in FIG. 24, the blue quantum dots 42b remaining in the blue electron transport layer 33b corresponding to the uncured portion are removed along with the blue electron transport layer 33b. After removal, the green light-emitting layer 35g is at least partially exposed. The etching solution 56 in step S35 is preferably the same alkaline solution as the developer 54 in step S34. When it is the same, steps S34 and S35 can be performed sequentially in a single step or in parallel, and thus the number of steps of the method for manufacturing the display device 2 can be further reduced. In other words, preferably, the uncured blue photosensitive resin 41b is soluble in the etching solution 56, and the cured blue photosensitive resin 43b is insoluble in the etching solution 56.

Note that in step S35, the blue electron transport layer 33b corresponding to the blue light-emitting layer 35b may be side-etched. Thus, in a plan view, the blue light-emitting layer 35b is preferably formed wider than an effective light-emitting region of the blue subpixel Pb, that is, an opening Ab of the edge cover 23. In addition, the blue light-emitting layer 35b is as wide as or wider than the blue electron transport layer 33b after etching in a plan view.

In subsequent step S36, first, as illustrated in FIG. 4 and FIG. 14, the red electron transport layer 33r is formed (step S37), and a red coating liquid 34r is applied on the red electron transport layer 33r (step S38). In step S37, the red electron transport layer 33r is formed in a solid shape over the red pixel electrode PEr and over the green pixel electrode PEg and the blue pixel electrode PEb. In addition, in step S38, the red coating liquid 34r is applied directly on the entire red electron transport layer 33r into a solid shape. The red coating liquid 34r is a third mixture in which the red quantum dots 42r are mixed into an uncured red photosensitive resin 41r (see FIG. 25). The red photosensitive resin 41r may be the same resin as the green photosensitive resin 41g or a different resin, and may be the same resin as the blue photosensitive resin 41b or a different resin.

Subsequently, in step S36, as illustrated in FIG. 4 and FIG. 15, the red coating liquid 34r is pattern-exposed using a red photomask 52r so as to form a pattern shape in which a portion to be the red light-emitting layer 35r is cured, and the other portion is not cured (step S39). At this time, as illustrated in FIG. 25, the red quantum dots 42r of the cured portion (i.e., the red light-emitting layer 35r) are fixed by the cured red photosensitive resin 43r. At the same time, a part of the red quantum dots 42r is adsorbed and/or mixed into the red electron transport layer 33r. Further, as illustrated in FIG. 15 and FIG. 25, the green light-emitting layer 35g is covered with the red electron transport layer 33r, and thus the red quantum dots 42r are not adsorbed or mixed into the green light-emitting layer 35g. Similarly, as illustrated in FIG. 15, the blue light-emitting layer 35b is covered with the red electron transport layer 33r, and thus the red quantum dots 42r are not adsorbed or mixed into the blue light-emitting layer 35b.

Subsequently, in step S36, as illustrated in FIG. 4 and FIG. 16, the uncured portion of the red coating liquid 34r is removed by the developer 54 to develop the red light-emitting layer 35r (i.e., the cured portion of the red coating liquid 34r) (third mixture removal step) (step S40). The developer 54 is an alkaline solution. In this way, the red light-emitting layer 35r is formed using a photolithography technique. At this time, as illustrated in FIG. 26, the red quantum dots 42r of the uncured portion are removed along with the uncured red photosensitive resin 41r. However, among the red quantum dots 42r of the uncured portion, a part of the red quantum dots 42r adsorbed or mixed into the red electron transport layer 33r remains in the surface and/or interior of the red electron transport layer 33r without being removed. In addition, as illustrated in FIG. 16 and FIG. 26, the green light-emitting layer 35g remains covered with the red electron transport layer 33r. Similarly, as illustrated in FIG. 16, the blue light-emitting layer 35b remains covered with the red electron transport layer 33r.

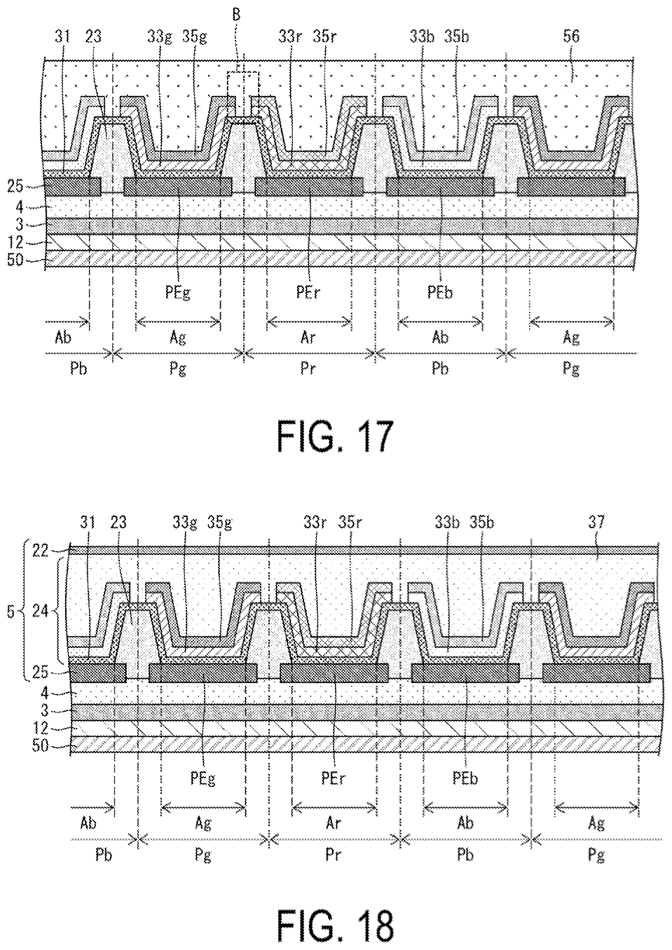

In step S36, finally, as illustrated in FIG. 4 and FIG. 17, the red light-emitting layer 35r is used as a mask to etch the red electron transport layer 33r using the etching solution 56 (step S41). This removes the red electron transport layer 33r corresponding to the uncured portion of the red coating liquid 34r. At this time, as illustrated in FIG. 27, the red quantum dots 42r remaining in the red electron transport layer 33r corresponding to the uncured portion are removed along with the red electron transport layer 33r. After removal, the green light-emitting layer 35g is at least partially exposed, and the blue light-emitting layer 35b is also at least partially exposed. The etching solution 56 in step S41 is preferably the same alkaline solution as the developer 54 in step S40. When it is the same, steps S40 and S41 can be performed sequentially in a single step or in parallel, and thus the number of steps of the method for manufacturing the display device 2 can be further reduced. In other words, preferably, the uncured red photosensitive resin 41r is soluble in the etching solution 56, and the cured red photosensitive resin 43r is insoluble in the etching solution.

Note that in step S41, the red electron transport layer 33r corresponding to the red light-emitting layer 35r may be side-etched. Thus, in a plan view, the red light-emitting layer 35r is preferably formed wider than an effective light-emitting region of the red subpixel Pr, that is, an opening Ar of the edge cover 23. Furthermore, in a plan view, the red light-emitting layer 35r is as wide as or wider than the red electron transport layer 33r after etching.

Then, as illustrated in FIG. 4 and FIG. 18, the hole transport layer 37 is formed on the green light-emitting layer 35g, the blue light-emitting layer 35b, and the red light-emitting layer 35r (step S42), and the anode 22 is formed on the hole transport layer 37 (step S43).

### Comparative Example

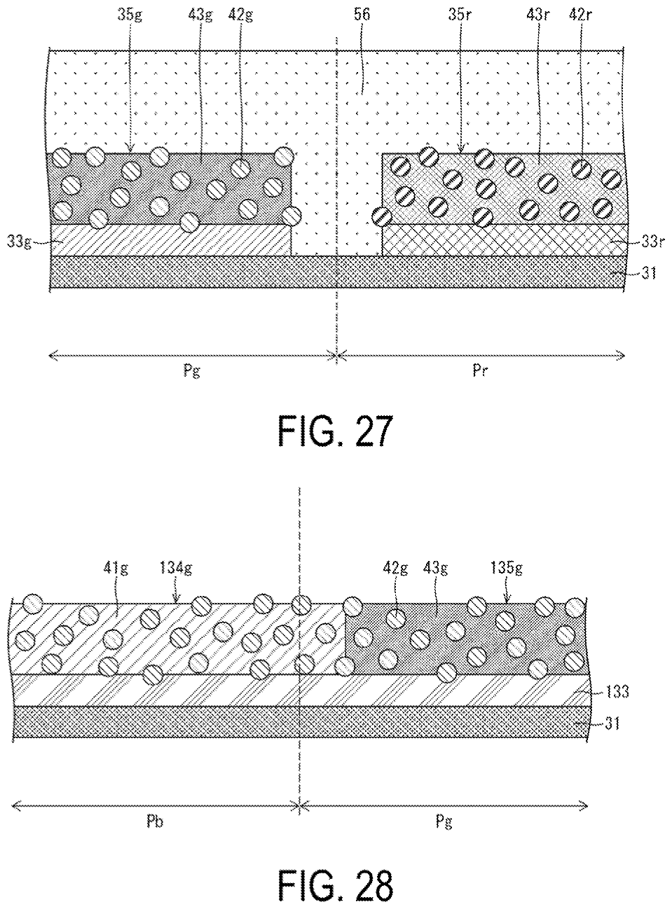

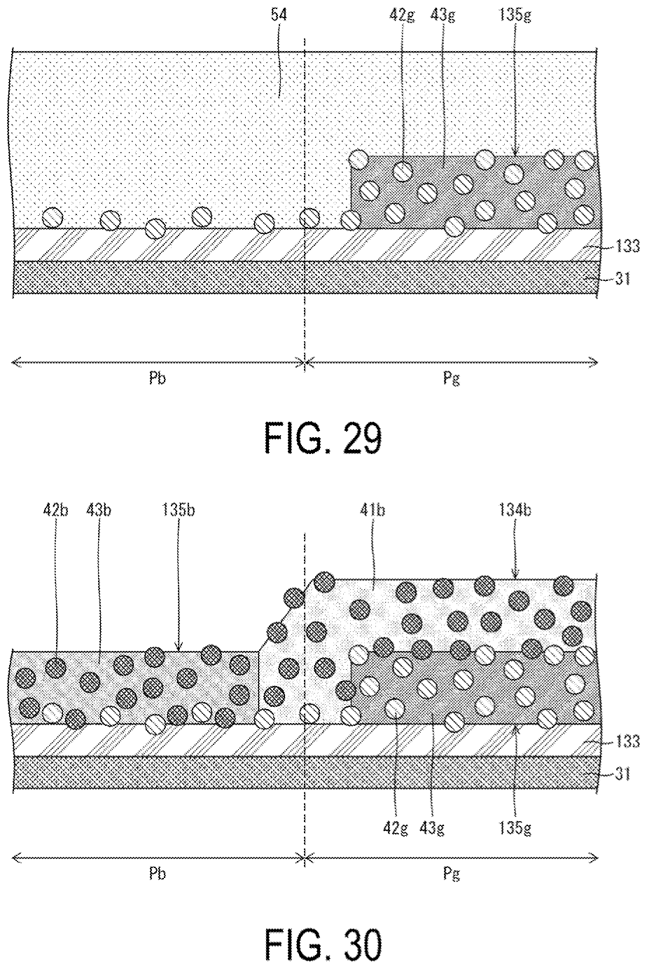

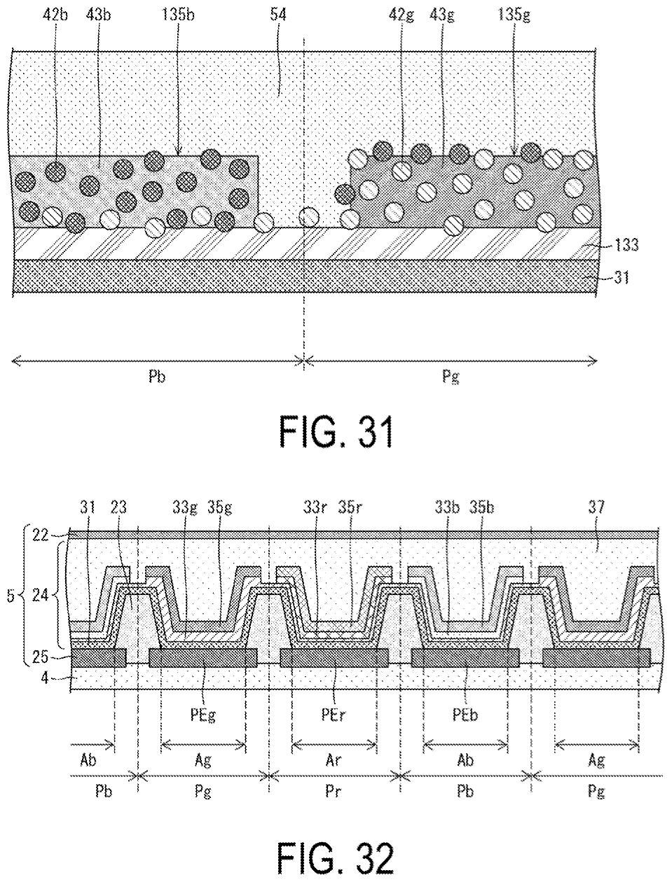

Hereinafter, with reference to FIGS. 28 to 31, a process for forming a green light-emitting layer 135g, a blue light-emitting layer 135b, and a red light-emitting layer 135r in a method for manufacturing a display device according to Comparative Example will be described. FIGS. 28 to 29 are schematic cross-sectional views illustrating portions of the process for forming the green light-emitting layer 135g according to Comparative Example. FIGS. 30 to 31 are schematic cross-sectional views illustrating portions of the process for forming the blue light-emitting layer 135b according to Comparative Example.

As illustrated in FIG. 28, in Comparative Example, an electron transport layer 133 is formed in a solid shape over the green subpixel Pg and the blue subpixel Pb (and, although not illustrated, the red subpixel Pr). Then, the green coating liquid 34g is applied directly, in a solid shape, on the entire electron transport layer 133. The green coating liquid 34g is then cured in a pattern shape. As illustrated in FIG. 29, the uncured portion of the green coating liquid 34g is then removed using the developer 54, thereby developing the green light-emitting layer 135g.

Subsequently, as illustrated in FIG. 30, the blue coating liquid 34b is formed in a solid shape over the green subpixel Pg and the blue subpixel Pb (and, although not illustrated, the red subpixel Pr). At this time, the blue coating liquid 34b is applied directly on the green light-emitting layer 135g and the electron transport layer 133. Then, the blue coating liquid 34b is cured in a pattern shape. As illustrated in FIG. 31, the uncured portion of the blue coating liquid 34b is then removed using the developer 54, thereby developing the blue light-emitting layer 135b.

Subsequently, although not illustrated, the red coating liquid 34r is formed in a solid shape over the green subpixel Pg, the blue subpixel Pb, and the red subpixel Pr. At this time, the red coating liquid 34r is applied directly on the green light-emitting layer 135g, the blue light-emitting layer 135b, and the electron transport layer 133. The red coating liquid 34r is then cured in a pattern shape. Although not illustrated, the uncured portion of the red coating liquid 34r is then removed using the developer 54, thereby developing the red light-emitting layer.

There are various problems in the light-emitting layer forming process according to such Comparative Example.

First, there is a problem in that the green quantum dots 42g remain in the electron transport layer 133 in the red subpixel Pr and the blue subpixel Pb as a residue.

As illustrated in FIG. 28, the green coating liquid 34g is applied directly onto the electron transport layer 133. Thus, a part of the green quantum dots 42g in the green coating liquid 34g is adsorbed and/or mixed in the electron transport layer 133. As illustrated in FIG. 29, when the uncured portion is removed, the green quantum dots 42g dispersed in the uncured green photosensitive resin 41g are removed along with the green photosensitive resin 41g. On the other hand, the green quantum dots 42g adsorbed and/or mixed in the electron transport layer 133 remain in the surface and/or interior of the electron transport layer 133 without being removed.

Similarly, there is a problem in that the blue quantum dots 42b remain in the electron transport layer 133 in the red subpixel Pr as a residue.

Secondly, there is a problem in that performance of the electron transport layer 133 in the blue subpixel Pb and the red subpixel Pr is lower than performance of the electron transport layer 133 in the green subpixel Pg.

As illustrated in FIG. 29, a portion of the electron transport layer 133 corresponding to the green light-emitting layer 135g is not exposed to the developer 54. On the other hand, the other portion of the electron transport layer 133 is exposed to the developer 54 for developing the green light-emitting layer 135g. The electron transport layer 133 exposed to the developer 54 has worse performance than the unexposed electron transport layer 133.

Similarly, there is a problem in that performance of the electron transport layer 133 in the red subpixel Pr is lower than performance of the electron transport layer 133 in the blue subpixel Pb.

In addition, there is a problem in that the blue quantum dots 42b remain in the green light-emitting layer 135g in the green subpixel Pg as a residue.

As illustrated in FIG. 30, the blue coating liquid 34b is applied directly onto the green light-emitting layer 135g. Thus, a part of the blue quantum dots 42b in the blue coating liquid 34b is adsorbed and/or mixed into the green light-emitting layer 135g. As illustrated in FIG. 31, when the uncured portion is removed, the blue quantum dots 42b dispersed in the uncured blue photosensitive resin 41b are removed along with the blue photosensitive resin 41b. On the other hand, the blue quantum dots 42b adsorbed and/or mixed in the green light-emitting layer 135g remain in the surface and/or interior of the green light-emitting layer 135g without being removed.

Similarly, there is a problem in that the red quantum dots 42r remain in the green light-emitting layer 135g in the green subpixel Pg and the blue light-emitting layer 135b in the blue subpixel Pb as a residue.

### Advantageous Effects

As described above, according to the method for manufacturing the display device 2 according to the first embodiment, the green light-emitting layer 35g is used as a mask to etch the green electron transport layer 33g (FIG. 9, step S29). Similarly, the blue light-emitting layer 35b is used as a mask to etch the blue electron transport layer 33b (FIG. 13, step S35), and the red light-emitting layer 35r is used as a mask to etch the red electron transport layer 33r (FIG. 17, step S41). Thus, the green electron transport layer 33g, the blue electron transport layer 33b, and the red electron transport layer 33r can be etched in a highly accurate pattern. This can improve the resolution and/or yield of the display device 2.

As described above, according to the method for manufacturing the display device 2 according to the first embodiment, the upper surface of the portion of the green electron transport layer 33g corresponding to the green light-emitting layer 35g is covered with the green light-emitting layer 35g and not exposed to the developer 54 and the etching solution 56. Similarly, the upper surface of the portion of the blue electron transport layer 33b corresponding to the blue light-emitting layer 35b is covered with the blue light-emitting layer 35b and not exposed to the developer 54 and the etching solution 56, and the upper surface of the portion of the red electron transport layer 33r corresponding to the red light-emitting layer 35r is covered with the red light-emitting layer 35r and not exposed to the developer 54 and the etching solution 56. Thus, the performance of the portion of the green electron transport layer 33g, the blue electron transport layer 33b, and the red electron transport layer 33r remaining in the finished product does not deteriorate, which leads to high reliability. Accordingly, it is possible to improve the reliability of the display device 2.

As described above, the method for manufacturing the display device 2 according to the first embodiment does not include a process of forming and removing a patterned photosensitive resin not included in the finished product. This can reduce the number of steps of the method for manufacturing the display device 2.

As described above, according to the method for manufacturing the display device 2 according to the first embodiment, the blue quantum dots 42b remaining in the blue electron transport layer 33b corresponding to the uncured portion of the blue coating liquid 34b are removed along with the blue electron transport layer 33b, and the red quantum dots 42r remaining in the red electron transport layer 33r corresponding to the uncured portion of the red coating liquid 34r are removed along with the red electron transport layer 33r. Furthermore, the blue quantum dots 42b and the red quantum dots 42r are not adsorbed or mixed in the green light-emitting layer 35g. Thus, the blue quantum dots 42b and the red quantum dots 42r that remain in the green subpixel Pg as a residue can be reduced, so that color purity of the green subpixel Pg can be improved.

As described above, according to the method for manufacturing the display device 2 according to the first embodiment, the green quantum dots 42g remaining in the green electron transport layer 33g corresponding to the uncured portion of the green coating liquid 34g are removed along with the green electron transport layer 33g, and the red quantum dots 42r remaining in the red electron transport layer 33r corresponding to the uncured portion of the red coating liquid 34r are removed along with the red electron transport layer 33r. Furthermore, the red quantum dots 42r are not adsorbed or mixed in the blue light-emitting layer 35b. As a result, similarly, the green quantum dots 42g and the red quantum dots 42r that remain in the blue subpixel Pb as a residual can be reduced, so that color purity of the blue subpixel Pb can be improved.

As described above, according to the method for manufacturing the display device 2 according to the first embodiment, the green quantum dots 42g remaining in the green electron transport layer 33g corresponding to the uncured portion of the green coating liquid 34g are removed along with the green electron transport layer 33g, and the blue quantum dots 42b remaining in the blue electron transport layer 33b corresponding to the uncured portion of the blue coating liquid 34b are removed along with the blue electron transport layer 33b. Thus, the green quantum dots 42g and the blue quantum dots 42b that remain in the red subpixel Pr as a residue can be reduced, so that color purity of the red subpixel Pr can be improved.

Such improvement of the color purity can improve color gamut of the display device 2.

As described above, according to the method for manufacturing the display device 2 according to the first embodiment, the green electron transport layer 33g, the blue electron transport layer 33b, and the red electron transport layer 33r are separated from each other. This can reduce a leakage current through the electron transport layers between the subpixels. Thus, it is possible to reduce power consumption of the display device 2.

### Modified Example

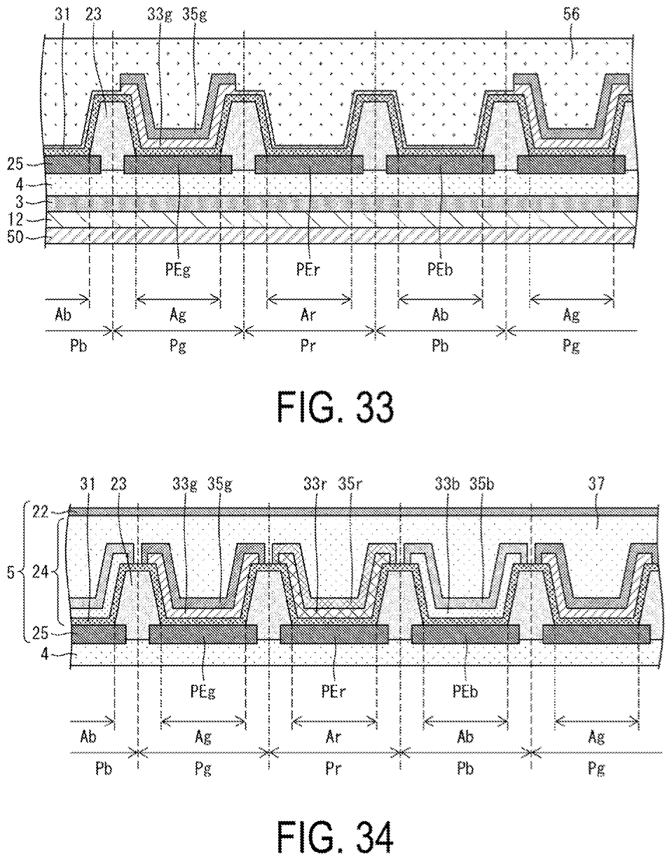

Hereinafter, a description will be given of a modified example of the first embodiment with reference to FIGS. 32 to 33.

FIG. 32 is a cross-sectional view illustrating a schematic configuration of the light-emitting element layer 5 in the display device 2 according to the modified example of the first embodiment. FIG. 33 is a schematic cross-sectional view illustrating a portion of an example of a process for forming the light-emitting element layer 5 illustrated in FIG. 32.

The light-emitting element layer 5 of the display device 2 according to the modified example illustrated in FIG. 32 is different from the light-emitting element layer 5 illustrated in FIG. 3, and includes the green electron transport layer 33g also in the red subpixel Pr and the blue subpixel Pb. The other configuration of the light-emitting element layer 5 illustrated in FIG. 32 is similar to the light-emitting element layer 5 illustrated in FIG. 3.

The green electron transport layer 33g according to the present modified example is formed in a solid shape over the green subpixel Pg, the blue subpixel Pb, and the red subpixel Pr. A first portion of the green electron transport layer 33g corresponding to the green light-emitting layer 35g is formed thick. A second portion of the green electron transport layer 33g corresponding to the blue light-emitting layer 35b and a third portion corresponding to the red light-emitting layer 35r are formed thinner than the first portion.

As illustrated in FIG. 33, such a green electron transport layer 33g can be manufactured by terminating the etching of the green electron transport layer 33g in step 29 at a time point when a lower portion of the green electron transport layer 33g remains. As a result, for a portion of the green electron transport layer 33g that does not correspond to the green light-emitting layer 35g, an upper portion contaminated with the green quantum dots 42g is removed, and a clean lower portion remains. Thus, in the red subpixel Rr and the blue subpixel Pb, the electron injection layer 31 (or cathode 25) is not exposed to the etching solution 56, so that performance deterioration of the electron injection layer 31 (or cathode 25) can be prevented.

Note that this modification is applicable to each of second to twelfth embodiments described below.

### Second Embodiment

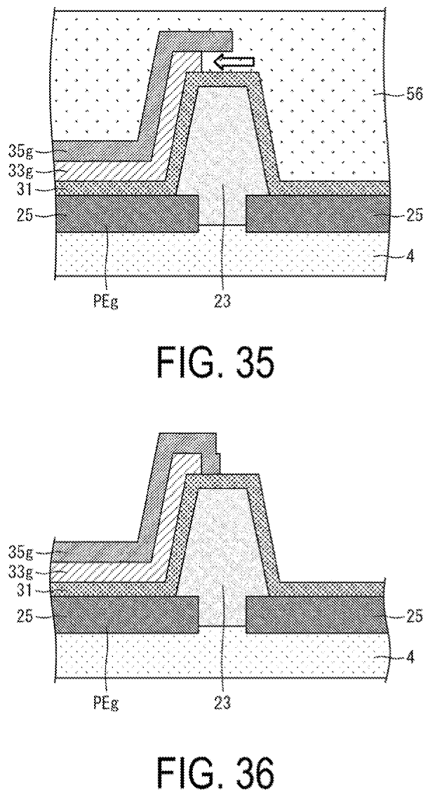

FIG. 34 is a cross-sectional view illustrating a schematic configuration of a light-emitting element layer 5 in a display device 2 according to a second embodiment of the disclosure. FIGS. 35 to 36 are schematic cross-sectional views, respectively, illustrating portions of an example of a process for forming a light-emitting element layer 5 illustrated in FIG. 34.

As illustrated in FIG. 34, the light-emitting element layer 5 according to the present embodiment has the same configuration as the light-emitting element layer 5 according to the first embodiment described above except that a side surface of a green electron transport layer 33g is covered with a green light-emitting layer 35g, a side surface of a blue electron transport layer 33b is covered with a blue light-emitting layer 35b, and a side surface of a red electron transport layer 33r is covered with a red light-emitting layer 35r.

According to the configuration according to the present embodiment, an upper surface and the side surface of the green electron transport layer 33g are covered with the green light-emitting layer 35g. This coating prevents direct contact between the green electron transport layer 33g and a hole transport layer 37, and thus a leakage current between a cathode 25 and an anode 22 which are a green pixel electrode PEg is reduced. Similarly, the coating of an upper surface and the side surface of the blue electron transport layer 33b by the blue light-emitting layer 35b reduces a leakage current between a cathode 25 and an anode 22 which are a blue pixel electrode PEb, and the coating of an upper surface and the side surface of the red electron transport layer 33r by the red light-emitting layer 35r reduces a leakage current between a cathode 25 and an anode 22 which are a red pixel electrode PEr.

Such a coating can be manufactured by further advancing etching in steps S29, S35, and S41 to perform side etching. Specifically, in step S29, as illustrated in FIG. 35, side etching is performed so as to remove a perimeter edge portion of a portion of the green electron transport layer 33g corresponding to the green light-emitting layer 35g. This eliminates a portion of the green electron transport layer 33g corresponding to the perimeter edge portion of the green light-emitting layer 35g, and as a result, the perimeter edge portion of the green light-emitting layer 35g is in a state of being free in an etching solution 56. As illustrated in FIG. 36, when the etching is ended, the etching solution 56 is eliminated, and thus the perimeter edge portion of the green light-emitting layer 35g is suspended to cover the side surface of the green electron transport layer 33g. Similarly, in step S35, side etching is performed so as to remove a perimeter edge portion of a portion of the blue electron transport layer 33b corresponding to the blue light-emitting layer 35b. Further, in step S41, side etching is performed so as to remove a perimeter edge portion of a portion of the red electron transport layer 33r corresponding to the red light-emitting layer 35r.

Note that the green light-emitting layer 35g is formed wider than an opening Ag of an edge cover 23 in such a manner that the green electron transport layer 33g after side etching covers the entire effective light-emitting region of the green subpixel Pg. Similarly, the blue light-emitting layer 35b is formed wider than an opening Ab of the edge cover 23, and the red light-emitting layer 35r is formed wider than an opening Ar of the edge cover 23.

By such a coating, the side surface of the green electron transport layer 33g is not exposed to the etching solution 56 in step S35, and thus it is possible to prevent unintended side etching of the green electron transport layer 33g and performance deterioration of the perimeter edge portion of the green electron transport layer 33g. Similarly, the side surface of the green electron transport layer 33g and the side surface of the blue electron transport layer 33b are not exposed to the etching solution 56 in step S41, and thus it is possible to prevent unintended side etching of the green electron transport layer 33g and the blue electron transport layer 33b and performance deterioration of the perimeter edge portions of the green electron transport layer 33g and the blue electron transport layer 33b. Thus, the method for manufacturing the display device 2 according to the second embodiment can further improve reliability of the display device 2 as compared to the method for manufacturing the display device 2 according to the first embodiment described above.

Furthermore, this coating prevents direct contact between the green electron transport layer 33g and the hole transport layer 37, and thus reduces a leakage current between the cathode 25 and the anode 22 which are the green pixel electrode PEg. Similarly, this coating reduces a leakage current between the cathode 25 and the anode 22 which are the blue pixel electrode PEb, and reduces a leakage current between the cathode 25 and the anode 22 which are the red pixel electrode PEr. Thus, as compared to the method for manufacturing the display device 2 according to the first embodiment, the method for manufacturing the display device 2 according to the second embodiment can further improve the luminous efficiency of the green subpixel Pg, the blue subpixel Pb, and the red subpixel Pr. This can reduce power consumption of the display device 2.

Similarly to the method for manufacturing the display device 2 according to the first embodiment described above, according to the method for manufacturing the display device 2 according to the second embodiment, the resolution and/or yield of the display device 2 can be improved. Furthermore, the number of steps of the method for manufacturing the display device 2 can be reduced. Furthermore, color gamut of the display device 2 can be improved. Furthermore, power consumption of the display device 2 can be reduced.

Note that an intermediate configuration between the configuration according to the first embodiment described above and the configuration according to the second embodiment is also included in the scope of the disclosure. For example, at least a part of the side surface of the green electron transport layer 33g may be covered with the green light-emitting layer 35g, at least a part of the side surface of the blue electron transport layer 33b may be covered with the blue light-emitting layer 35b, and/or at least a part of the side surface of the red electron transport layer 33r may be covered with the red light-emitting layer 35r.

### Third Embodiment

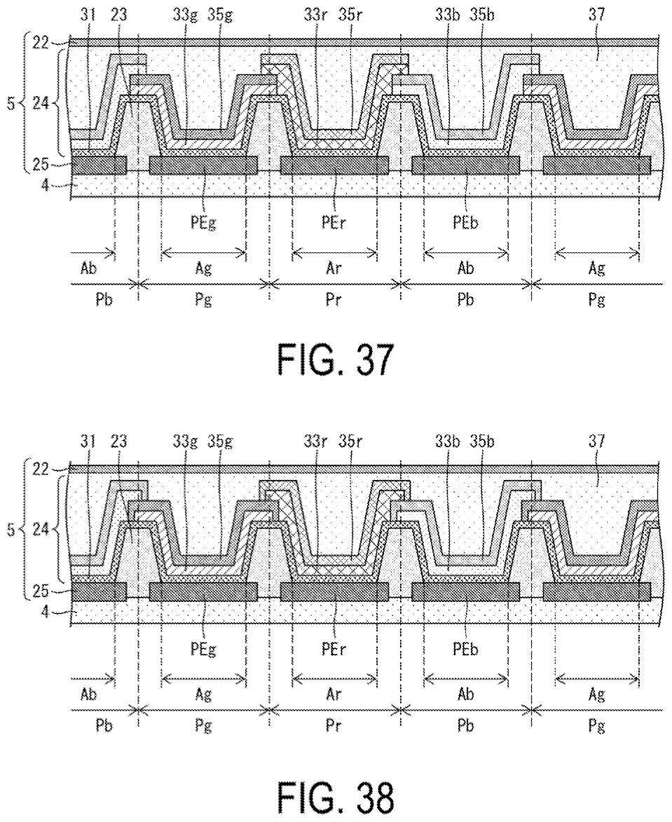

FIG. 37 is a cross-sectional view illustrating a schematic configuration of a light-emitting element layer 5 in a display device 2 according to a third embodiment of the disclosure. As illustrated in FIG. 37, the light-emitting element layer 5 according to the third embodiment has the same configuration as the light-emitting element layer 5 according to the first embodiment described above except the following three points.

One point is a point where a part of perimeter edge portions of a green electron transport layer 33g and a green light-emitting layer 35g (a left side portion in FIG. 37) overlaps with a part of perimeter edge portions of a blue electron transport layer 33b and a blue light-emitting layer 35b (a right side portion of FIG. 37). That is, the portion of the blue electron transport layer 33b overlaps with the portion of the green electron transport layer 33g with the green light-emitting layer 35g interposed therebetween.

Another point is a point where another part of the perimeter edge portions of the green electron transport layer 33g and the green light-emitting layer 35g (the right side portion in FIG. 37) overlaps with a part of perimeter edge portions of a red electron transport layer 33r and a red light-emitting layer 35r (the left side portion in FIG. 37). That is, the portion of the red electron transport layer 33r overlaps with another portion of the green electron transport layer 33g with the green light-emitting layer 35g interposed therebetween.

Still another point is a point where another part of the perimeter edge portions of the blue electron transport layer 33b and the blue light-emitting layer 35b (the left side portion in FIG. 37) overlaps with another part of the perimeter edge portions of the red electron transport layer 33r and the red light-emitting layer 35r (the right side portion in FIG. 37). That is, another part of the red electron transport layer 33r overlaps with another part of the blue electron transport layer 33b with the blue light-emitting layer 35b interposed therebetween.

As a result of such superimposition, unlike the configurations according to the first and second embodiments described above, in the configuration according to the third embodiment, the green electron transport layer 33g, the blue electron transport layer 33b, and the red electron transport layer 33r are in contact with each other.

Note that, although not illustrated, any portion of the perimeter edge portions of the green electron transport layer 33g and the green light-emitting layer 35g overlaps with at least one of the perimeter edge portions of the blue electron transport layer 33b and the blue light-emitting layer 35b, and the perimeter edge portions of the red electron transport layer 33r and the red light-emitting layer 35r. Similarly, any portion of the perimeter edge portions of the blue electron transport layer 33b and the blue light-emitting layer 35b overlaps with at least one of the perimeter edge portions of the green electron transport layer 33g and the green light-emitting layer 35g, and the perimeter edge portions of the red electron transport layer 33r and the red light-emitting layer 35r, and any portion of the perimeter edge portions of the red electron transport layer 33r and the red light-emitting layer 35r overlaps with at least one of the perimeter edge portions of the green electron transport layer 33g and the green light-emitting layer 35g, and the perimeter edge portions of the red electron transport layer 33r and the red light-emitting layer 35r.

By such superposition, a part of the side surface of the green electron transport layer 33g is covered with the blue electron transport layer 33b or the red electron transport layer 33r. This coating prevents direct contact between the green electron transport layer 33g and a hole transport layer 37, and thus a leakage current between a cathode 25 and an anode 22 which are a green pixel electrode PEg is reduced. Furthermore, the other portion of the side surface of the green electron transport layer 33g is covered with the red electron transport layer 33r. This coating similarly reduces a leakage current between the cathode 25 and the anode 22 which are the green pixel electrode PEg. Furthermore, a part of the side surface of the blue electron transport layer 33b is covered with the red electron transport layer 33r. This coating similarly reduces a leakage current between a cathode 25 and an anode 22 which are a blue pixel electrode PEb. Thus, as compared to the method for manufacturing the display device 2 according to the first embodiment described above, the method for manufacturing the display device 2 according to the third embodiment can further improve the luminous efficiency of the green subpixel Pg, the blue subpixel Pb, and the red subpixel Pr. This can reduce power consumption of the display device 2.

Similarly to the method for manufacturing the display device 2 according to the first embodiment described above, according to the method for manufacturing the display device 2 according to the third embodiment, the resolution and/or yield of the display device 2 can be improved. Furthermore, it is possible to improve reliability of the display device 2. Furthermore, the number of steps of the method for manufacturing the display device 2 can be reduced. Furthermore, color gamut of the display device 2 can be improved. Furthermore, power consumption of the display device 2 can be reduced.

Note that an intermediate configuration between the configuration according to the first embodiment described above and the configuration according to the third embodiment is also included in the scope of the disclosure. Furthermore, as to the order in which the perimeter edge portions overlap, any order may be acceptable. For example, superimposition may be in the order of green, red, and blue, blue, green, and red, blue, red, and green, red, green, and blue, or red, blue, and green.

### Fourth Embodiment

FIG. 38 is a cross-sectional view illustrating a schematic configuration of a light-emitting element layer 5 in a display device 2 according to a fourth embodiment of the disclosure.

As illustrated in FIG. 38, a green light-emitting layer 35g covers an entire side surface of a green electron transport layer 33g, a blue light-emitting layer 35b covers an entire side surface of a blue electron transport layer 33b, and a red light-emitting layer 35r covers an entire side surface of a red electron transport layer 33r. Furthermore, a portion of the blue electron transport layer 33b overlaps with a portion of the green electron transport layer 33g with the green light-emitting layer 35g interposed therebetween, a portion of the red electron transport layer 33r overlaps with another portion of the green electron transport layer 33g with the green light-emitting layer 35g interposed therebetween, and another portion of the red electron transport layer 33r overlaps with another portion of the blue electron transport layer 33b with the blue light-emitting layer 35b interposed therebetween.

As illustrated in FIG. 38, the light-emitting element layer 5 according to the fourth embodiment has the same configuration as the light-emitting element layer 5 according to the second embodiment described above except the following three points. One point is a point where a part of perimeter edge portions of the green electron transport layer 33g and the green light-emitting layer 35g (a left side portion in FIG. 37) overlaps with a part of perimeter edge portions of the blue electron transport layer 33b and the blue light-emitting layer 35b (a right side portion of FIG. 37). Another point is a point where another part of the perimeter edge portions of the green electron transport layer 33g and the green light-emitting layer 35g (the right side portion in FIG. 37) overlaps with a part of the perimeter edge portions of the red electron transport layer 33r and the red light-emitting layer 35r (the left side portion in FIG. 37). Still another point is a point where another part of the perimeter edge portions of the blue electron transport layer 33b and the blue light-emitting layer 35b (the left side portion in FIG. 37) overlaps with another part of the perimeter edge portions of the red electron transport layer 33r and the red light-emitting layer 35r (the right side portion in FIG. 37).

As illustrated in FIG. 38, the light-emitting element layer 5 according to the fourth embodiment has the same configuration as the light-emitting element layer 5 according to the third embodiment described above except that a side surface of the green electron transport layer 33g is covered with the green light-emitting layer 35g, a side surface of the blue electron transport layer 33b is covered with the blue light-emitting layer 35b, and a side surface of the red electron transport layer 33r is covered with the red light-emitting layer 35r. Note that, similarly to the configurations according to the first and second embodiments described above, in the configuration according to the fourth embodiment, this coating separates the green electron transport layer 33g, the blue electron transport layer 33b, and the red electron transport layer 33r from each other.

That is, the configuration according to the fourth embodiment is a configuration obtained by combining the configuration according to the second embodiment described above to the configuration according to the third embodiment described above. Thus, as compared to the method for manufacturing the display device 2 according to the first embodiment, the method for manufacturing the display device 2 according to the fourth embodiment can further improve the reliability of the display device 2, and can reduce the power consumption of the display device 2.

Similarly to the method for manufacturing the display device 2 according to the first embodiment described above, according to the method for manufacturing the display device 2 according to the fourth embodiment, the resolution and/or yield of the display device 2 can be improved. Furthermore, the number of steps of the method for manufacturing the display device 2 can be reduced. Furthermore, color gamut of the display device 2 can be improved. Furthermore, power consumption of the display device 2 can be reduced.

Note that an intermediate configuration between the configurations according to the first, second, and third embodiments described above and the configuration according to the fourth embodiment is also included in the scope of the disclosure.

### Fifth Embodiment

### Configuration of Light-Emitting Element Layer

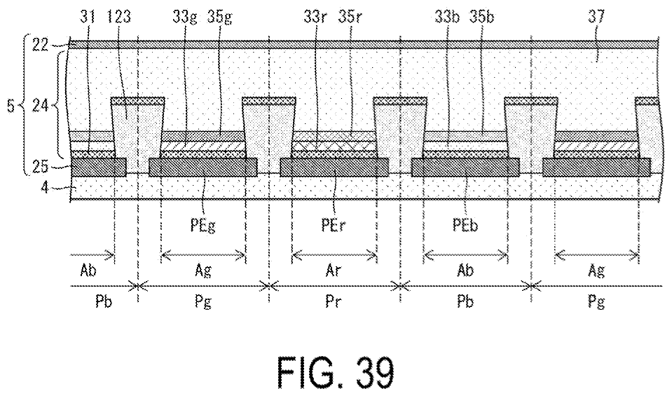

FIG. 39 is a cross-sectional view illustrating a schematic configuration of a light-emitting element layer 5 in a display device 2 according to a fifth embodiment of the disclosure. As illustrated in FIG. 39, the light-emitting element layer 5 according to the present embodiment has the same configuration as the light-emitting element layer 5 according to the first embodiment described above except that an insulating reverse tapered edge cover 123 is provided instead of the edge cover 23.

The reverse tapered edge cover 123 according to the present embodiment has the same configuration as the edge cover 23 according to the first embodiment described above except that inclination of the side surface is reversed. The reverse tapered edge cover 123 covering a perimeter edge portion of a green pixel electrode PEg is formed in such a manner that an angle formed between a side surface of the reverse tapered edge cover 123 on the green pixel electrode PEg side and a surface of the green pixel electrode PEg is an acute angle. Similarly, the reverse tapered edge cover 123 covering a perimeter edge portion of a blue pixel electrode PEb is formed in such a manner that an angle formed between a side surface of the reverse tapered edge cover 123 on the blue pixel electrode PEb side and a surface of the blue pixel electrode PEb is an acute angle. Similarly, the reverse tapered edge cover 123 covering a perimeter edge portion of a red pixel electrode PEr is formed in such a manner that an angle formed between a side surface of the reverse tapered edge cover 123 on the red pixel electrode PEr side and a surface of the red pixel electrode PEr is an acute angle.

The reverse tapered edge cover 123 covers side surfaces of a green electron transport layer 33g, a blue electron transport layer 33b, and a red electron transport layer 33r.

By such a coating, the side surface of the green electron transport layer 33g is not exposed to the etching solution 56 in step S35, and thus it is possible to prevent unintended side etching of the green electron transport layer 33g and performance deterioration of the perimeter edge portion of the green electron transport layer 33g. Similarly, the side surface of the green electron transport layer 33g and the side surface of the blue electron transport layer 33b are not exposed to the etching solution 56 in step S41, and thus it is possible to prevent unintended side etching of the green electron transport layer 33g and the blue electron transport layer 33b and performance deterioration of the perimeter edge portions of the green electron transport layer 33g and the blue electron transport layer 33b. Thus, the method for manufacturing the display device 2 according to the fifth embodiment can further improve the reliability of the display device 2 as compared to the method for manufacturing the display device 2 according to the first embodiment described above.

Furthermore, this coating prevents direct contact between the green electron transport layer 33g and a hole transport layer 37, and thus reduces a leakage current between a cathode 25 and an anode 22 which are the green pixel electrode PEg. Similarly, this coating reduces a leakage current between a cathode 25 and an anode 22 which are the blue pixel electrode PEb, and reduces a leakage current between a cathode 25 and an anode 22 which are the red pixel electrode PEr. Thus, as compared to the method for manufacturing the display device 2 according to the first embodiment, the method for manufacturing the display device 2 according to the fifth embodiment can further improve the luminous efficiency of the green subpixel Pg, the blue subpixel Pb, and the red subpixel Pr. This can reduce power consumption of the display device 2.

Similarly to the method for manufacturing the display device 2 according to the first embodiment described above, according to the method for manufacturing the display device 2 according to the fifth embodiment, the resolution and/or yield of the display device 2 can be improved. Furthermore, the number of steps of the method for manufacturing the display device 2 can be reduced. Furthermore, color gamut of the display device 2 can be improved. Furthermore, power consumption of the display device 2 can be reduced.

### Light-Emitting Element Layer Forming Process

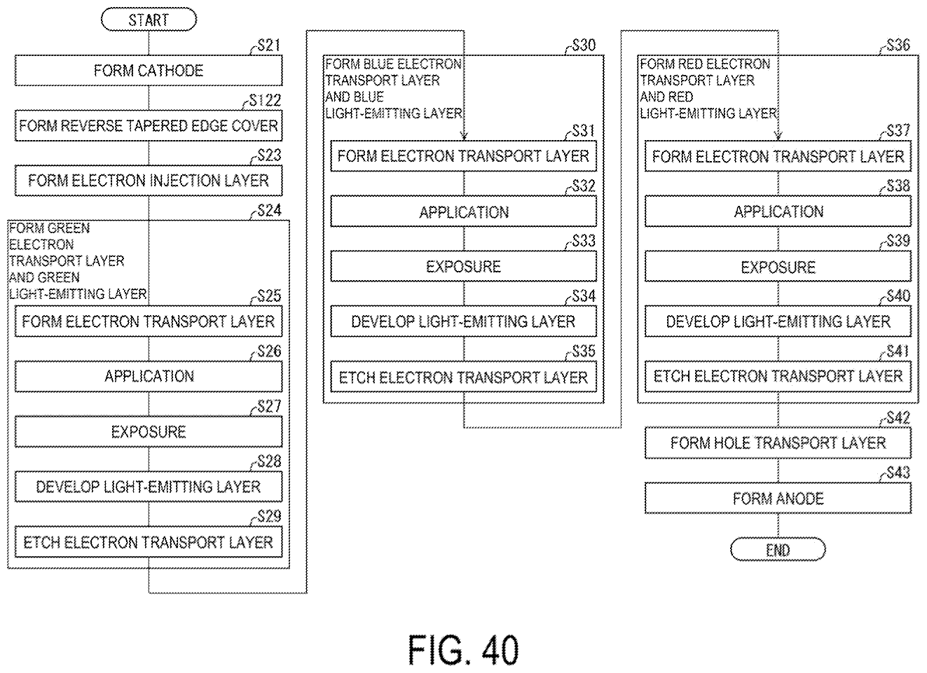

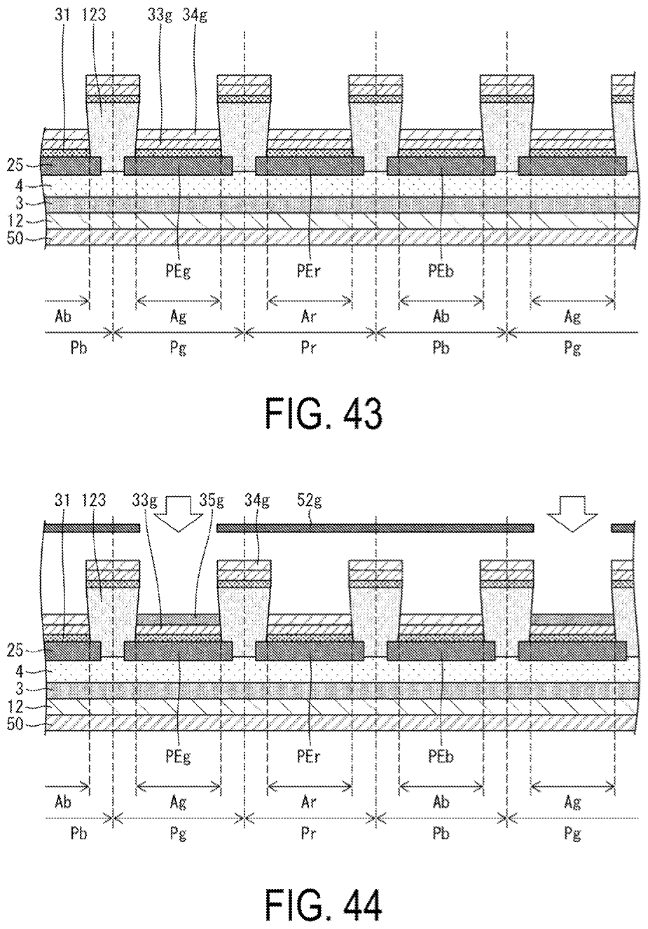

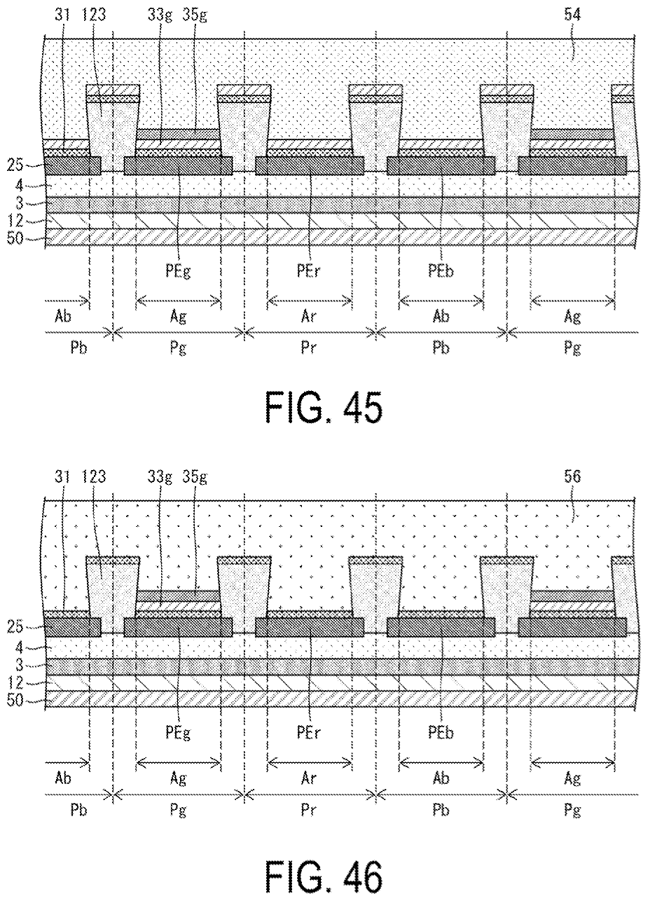

Hereinafter, with reference to FIGS. 40 to 47, a process for forming the light-emitting element layer 5 (step S4 in FIG. 1) in the method for manufacturing the display device 2 according to the fifth embodiment of the disclosure will be described. FIG. 40 is a flowchart illustrating an example of the process for forming the light-emitting element layer 5 illustrated in FIG. 39. FIGS. 40 to 47 are schematic cross-sectional views illustrating portions of the example of the process for forming the light-emitting element layer 5 illustrated in FIG. 39.

The process according to the fifth embodiment illustrated in FIG. 40 has the same steps in the same order as the process according to the first embodiment described above illustrated in FIG. 4 except that step S122 is performed instead of step S22.

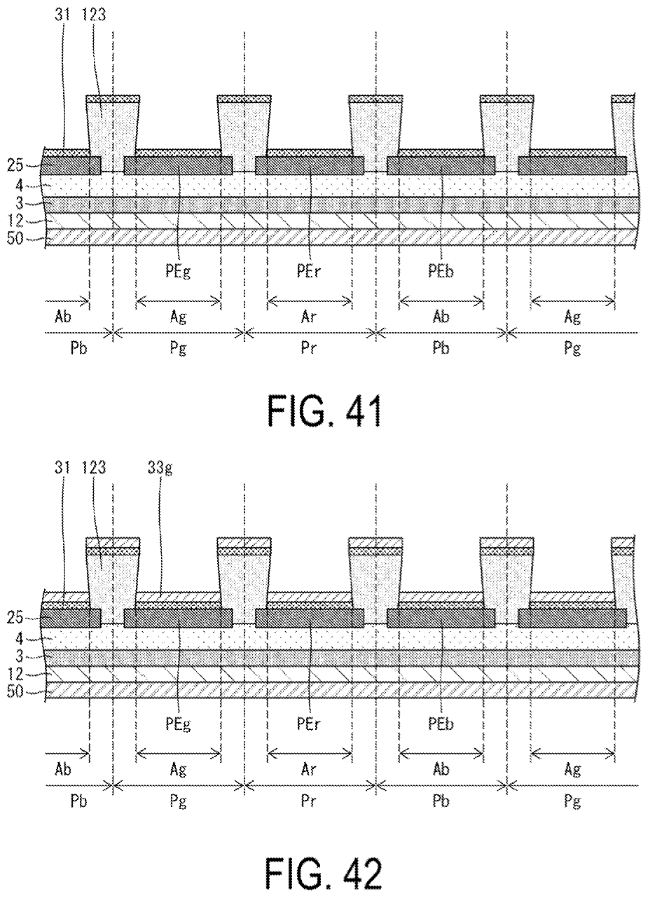

As illustrated in FIG. 40 and FIG. 41, following step S21, the reverse tapered edge cover 123 is formed so as to cover an edge of each cathode 25 (bank forming step) (step S122). Subsequently, an electron injection layer 31 is formed to cover the cathodes 25 (step S23). In step S23, the electron injection layer 31 is not formed on the side surface of the reverse tapered edge cover 123. Thus, the electron injection layer 31 is step-cut and formed on the cathode 25 and on the reverse tapered edge cover 123.

As illustrated in FIG. 40 and FIGS. 42 to 43, subsequently, the green electron transport layer 33g is similarly step-cut to be formed (step S25), and a green coating liquid 34g is step-cut to be applied (step S26). Then, as illustrated in FIG. 40 and FIG. 44, the green coating liquid 34g is exposed in such a manner that a portion to be the green light-emitting layer 35g is cured and the other portion is not cured (step S27).

As illustrated in FIGS. 40 and FIGS. 45 to 46, subsequently, the green light-emitting layer 35g is developed (step S28), and the green electron transport layer 33g is etched (step S29). In steps after step S27, the side surface of the green electron transport layer 33g is covered with the reverse tapered edge cover 123, and the upper surface of the green electron transport layer 33g is covered with the green light-emitting layer 35g. This can prevent side etching and performance deterioration of the green electron transport layer 33g.

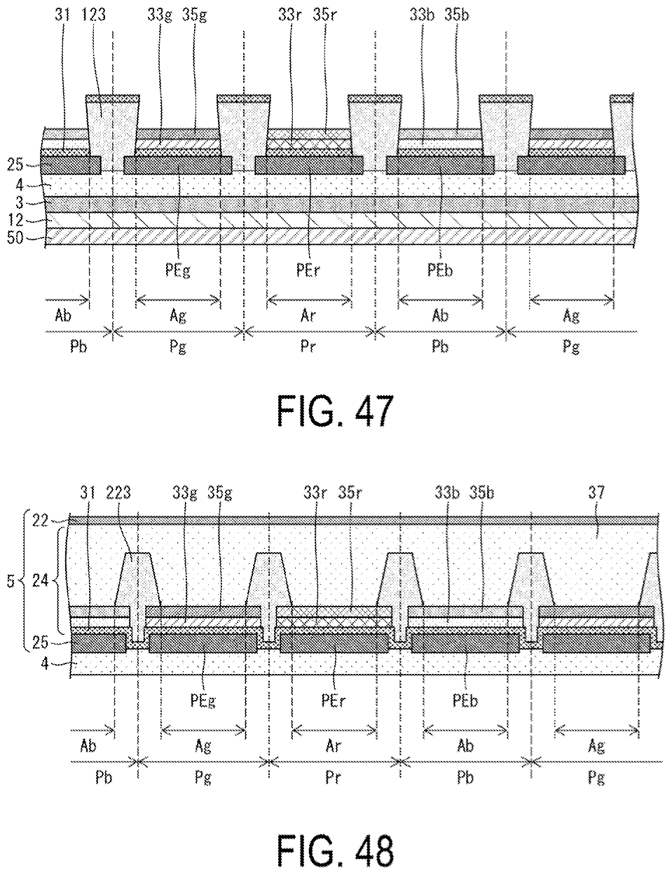

As illustrated in FIG. 40 and FIG. 47, similarly, step S30 including steps S31 to S35 and step S36 including steps S37 to S41 are performed. In steps after step S33, the side surface of the blue electron transport layer 33b is covered with the reverse tapered edge cover 123, and the upper surface of the blue electron transport layer 33b is covered with the blue light-emitting layer 35b. This can prevent side etching and performance deterioration of the blue electron transport layer 33b. In steps after step S39, the side surface of the red electron transport layer 33r is covered with the reverse tapered edge cover 123, and the upper surface of the red electron transport layer 33r is covered with the red light-emitting layer 35r. This can prevent side etching and performance deterioration of the red electron transport layer 33r.

Then, as illustrated in FIG. 40, the hole transport layer 37 is formed (step S42), and the anode 22 is formed (step S43).

### Sixth Embodiment

### Configuration of Light-Emitting Element Layer

FIG. 48 is a cross-sectional view illustrating a schematic configuration of a light-emitting element layer 5 in a display device 2 according to a sixth embodiment of the disclosure. As illustrated in FIG. 48, the light-emitting element layer 5 according to the sixth embodiment has the same configuration as the light-emitting element layer 5 according to the first embodiment described above except that an edge cover 223 is provided instead of the edge cover 23. The edge cover 223 is formed in an upper layer above a green light-emitting layer 35g, a blue light-emitting layer 35b, and a red light-emitting layer 35r and has insulating properties.

The edge cover 223 according to the sixth embodiment has the same configuration as the edge cover 23 according to the first embodiment described above except that the edge cover 223 covers a perimeter edge portion of the green light-emitting layer 35g, a perimeter edge portion of the blue light-emitting layer 35b, and a perimeter edge portion of the red light-emitting layer 35r.

The edge cover 223 covers side surfaces of a green electron transport layer 33g, a blue electron transport layer 33b, and a red electron transport layer 33r. Thus, the edge cover 223 according to the sixth embodiment is less likely to generate an abnormal electric field and an abnormal current in the periphery.

By such a coating, the side surface of the green electron transport layer 33g is not exposed to the etching solution 56 in step S35, and thus it is possible to prevent unintended side etching of the green electron transport layer 33g and performance deterioration of the perimeter edge portion of the green electron transport layer 33g. Similarly, the side surface of the green electron transport layer 33g and the side surface of the blue electron transport layer 33b are not exposed to the etching solution 56 in step S41, and thus it is possible to prevent unintended side etching of the green electron transport layer 33g and the blue electron transport layer 33b and performance deterioration of the perimeter edge portions of the green electron transport layer 33g and the blue electron transport layer 33b. Thus, as compared to the method for manufacturing the display device 2 according to the first embodiment, the method for manufacturing the display device 2 according to the sixth embodiment can further improve the reliability of the display device 2.

Furthermore, this coating prevents direct contact between the green electron transport layer 33g and a hole transport layer 37, and thus reduces a leakage current between a cathode 25 and an anode 22 which are a green pixel electrode PEg. Similarly, this coating reduces a leakage current between a cathode 25 and an anode 22 which are a blue pixel electrode PEb, and reduces a leakage current between a cathode 25 and an anode 22 which are a red pixel electrode PEr. Thus, as compared to the method for manufacturing the display device 2 according to the sixth embodiment, the method for manufacturing the display device 2 according to the fifth embodiment described above can further improve the luminous efficiency of the green subpixel Pg, the blue subpixel Pb, and the red subpixel Pr. This can reduce power consumption of the display device 2.

Similarly to the method for manufacturing the display device 2 according to the first embodiment described above, according to the method for manufacturing the display device 2 according to the sixth embodiment, the resolution and/or yield of the display device 2 can be improved. Furthermore, the number of steps of the method for manufacturing the display device 2 can be reduced. Furthermore, color gamut of the display device 2 can be improved. Furthermore, power consumption of the display device 2 can be reduced.

### Light-Emitting Element Layer Forming Process

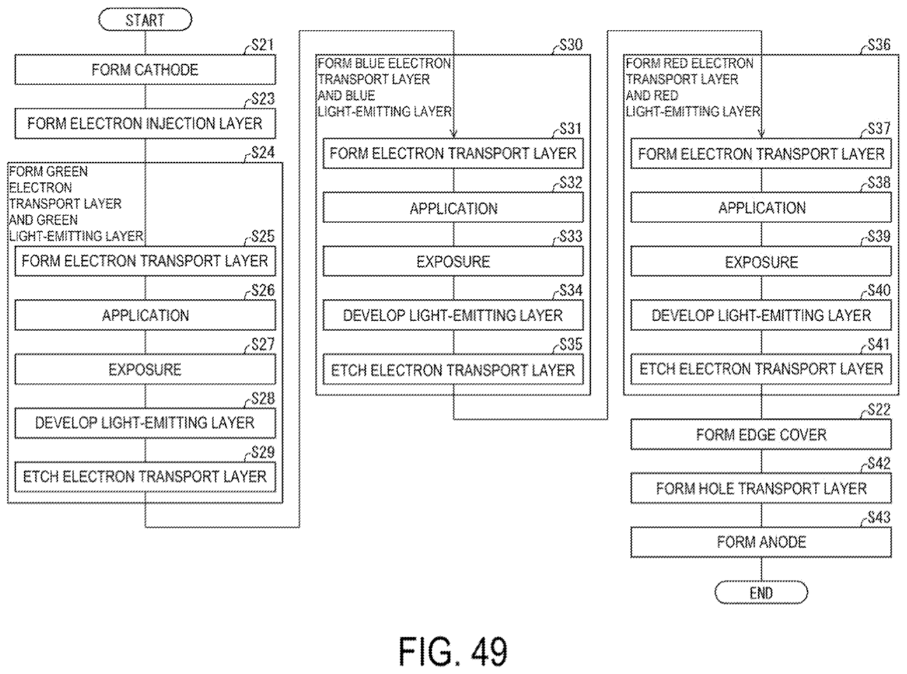

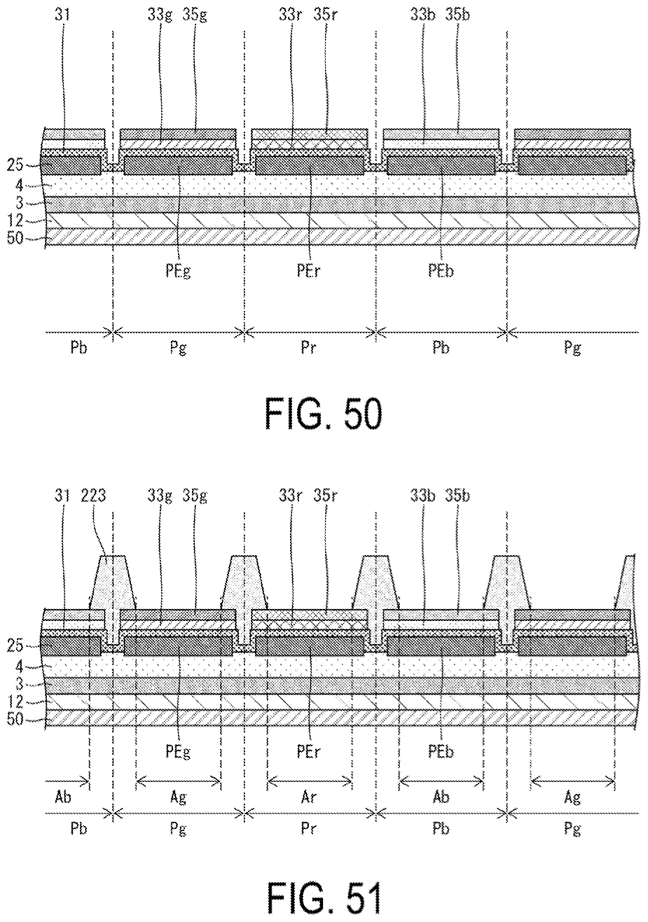

Hereinafter, with reference to FIGS. 49 to 52, a process for forming the light-emitting element layer 5 (step S4 in FIG. 1) in the method for manufacturing the display device 2 according to the sixth embodiment of the disclosure will be described. FIG. 49 is a flowchart illustrating an example of a process for forming the light-emitting element layer 5 illustrated in FIG. 48. FIGS. 50 to 52 are schematic cross-sectional views illustrating portions of the example of the process for forming the light-emitting element layer 5 illustrated in FIG. 48.

The process according to the sixth embodiment illustrated in FIG. 49 has the same steps in the same order as the process according to the first embodiment illustrated in FIG. 4 except that step S22 is performed after steps S24, S30 and S36, and before step S42.

As illustrated in FIG. 49 and FIG. 50, following formation of the cathode 25 (step S21), an electron injection layer is formed without forming the edge cover (step S24), and formation of the green electron transport layer 33g and the green light-emitting layer 35g (step S24), formation of the blue electron transport layer 33b and the blue light-emitting layer 35b (step S30), and formation of the red electron transport layer 33r and the red light-emitting layer 35r (step S36) are further performed.

Then, as illustrated in FIG. 49 and FIG. 51, the edge cover 223 is formed so as to cover the perimeter edge portion of the green light-emitting layer 35g, the perimeter edge portion of the blue light-emitting layer 35b, and the perimeter edge portion of the red light-emitting layer 35r (step S22).

Then, as illustrated in FIG. 49, the hole transport layer 37 is formed (step S42), and the anode 22 is formed (step S43).

### Seventh Embodiment

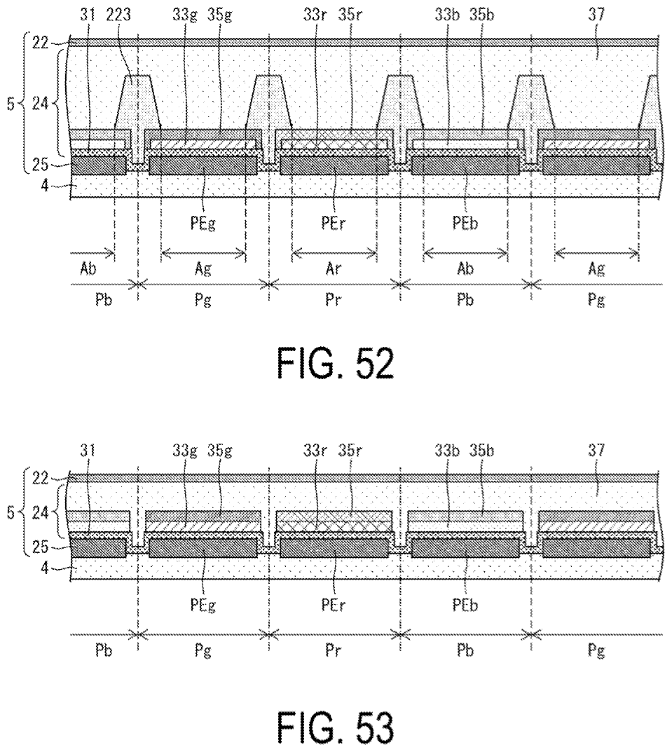

FIG. 52 is a cross-sectional view illustrating a schematic configuration of a light-emitting element layer 5 in a display device 2 according to a seventh embodiment of the disclosure.

As illustrated in FIG. 52, the light-emitting element layer 5 according to the seventh embodiment has the same configuration as the light-emitting element layer 5 according to the second embodiment described above except that an edge cover 223 formed in an upper layer above a green light-emitting layer 35g, a blue light-emitting layer 35b, and a red light-emitting layer 35r is provided.

As illustrated in FIG. 52, the light-emitting element layer 5 according to the seventh embodiment has the same configuration as the light-emitting element layer 5 according to the sixth embodiment described above except that a side surface of a green electron transport layer 33g is covered with the green light-emitting layer 35g, a side surface of a blue electron transport layer 33b is covered with the blue light-emitting layer 35b, and a side surface of a red electron transport layer 33r is covered with the red light-emitting layer 35r.

That is, the configuration according to the seventh embodiment is a configuration obtained by combining the configuration according to the second embodiment described above to the configuration according to the sixth embodiment described above. Thus, the method for manufacturing the display device 2 according to the seventh embodiment can exhibit the same effects as those of the methods for manufacturing the display device 2 according to the second and sixth embodiments described above.

Note that an intermediate configuration between the configuration according to the sixth embodiment described above and the configuration according to the seventh embodiment is also included in the scope of the disclosure.

### Eighth Embodiment

### Configuration of Light-Emitting Element Layer

FIG. 53 is a cross-sectional view illustrating a schematic configuration of a light-emitting element layer 5 in a display device 2 according to an eighth embodiment of the disclosure. As illustrated in FIG. 53, the light-emitting element layer 5 according to the eighth embodiment has the same configuration as the light-emitting element layer 5 according to the first embodiment described above except that no edge cover is provided. Thus, it is possible to further reduce the number of steps of the method for manufacturing the display device 2 according to the eighth embodiment as compared to the method for manufacturing the display device 2 according to the first embodiment described above.

Further, similarly to the method for manufacturing the display device 2 according to the first embodiment described above, according to the method for manufacturing the display device 2 according to the eighth embodiment, the resolution and/or yield of the display device 2 can be improved. Furthermore, it is possible to further improve the reliability of the display device 2. Furthermore, color gamut of the display device 2 can be improved. Furthermore, power consumption of the display device 2 can be reduced.

No edge cover is formed between a green electron transport layer 33g and a green light-emitting layer 35g and between a blue electron transport layer 33b and a blue light-emitting layer 35b in the light-emitting element layer 5 according to the eighth embodiment. Thus, between these, as illustrated in FIG. 53, only a hole transport layer 37 is formed, or, although not illustrated, only both the hole transport layer 37 and an anode 22 are formed, or only the anode 22 is formed.

### Light-Emitting Element Layer Forming Process

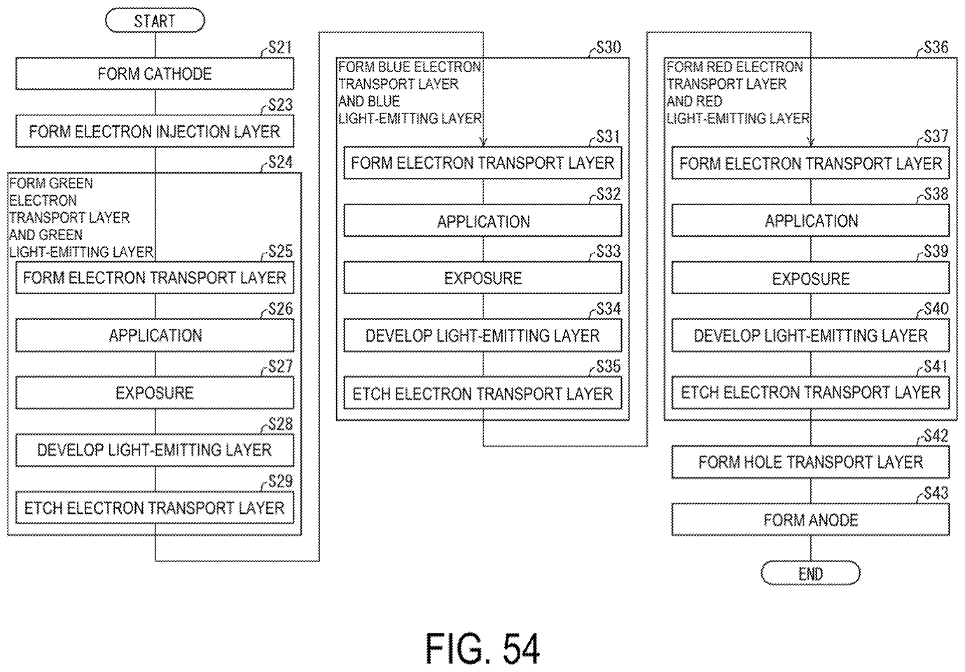

Hereinafter, with reference to FIG. 54, a process for forming the light-emitting element layer 5 (step S4 in FIG. 1) in the method for manufacturing the display device 2 according to the eighth embodiment of the disclosure will be described. FIG. 54 is a flowchart illustrating the process for forming the light-emitting element layer 5 illustrated in FIG. 53.

The process according to the eighth embodiment illustrated in FIG. 54 has the same steps in the same order as the process according to the first embodiment described above illustrated in FIG. 4 except that step S22 is not included.

Thus, as illustrated in FIG. 54 and FIG. 50, similarly to the sixth embodiment described above, following formation of a cathode 25 (step S21), an electron injection layer is formed without forming an edge cover (step S24), and formation of the green electron transport layer 33g and the green light-emitting layer 35g (step S24), formation of the blue electron transport layer 33b and the blue light-emitting layer 35b (step S30), and formation of the red electron transport layer 33r and the red light-emitting layer 35r (step S36) are further performed.

Then, as illustrated in FIG. 54, the hole transport layer 37 is formed without forming an edge cover (step S42), and the anode 22 is formed (step S43).

The process according to the eighth embodiment does not include the step of forming the edge cover as compared to the processes according to the first to seventh embodiments described above, and thus can further reduce the number of steps in manufacturing the display device.

### Ninth Embodiment

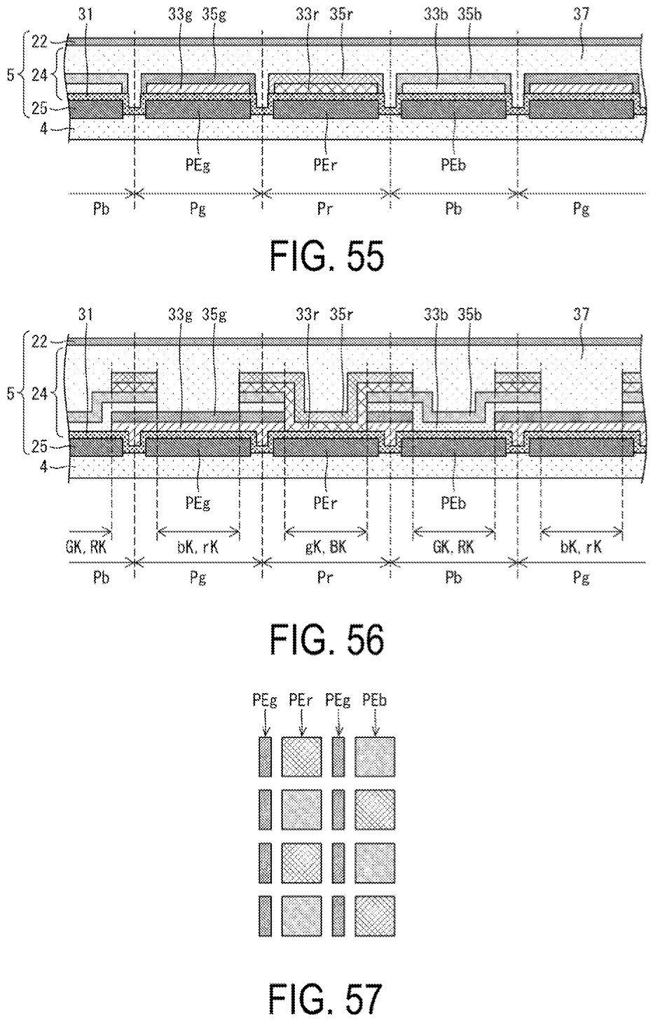

FIG. 55 is a cross-sectional view illustrating a schematic configuration of a light-emitting element layer 5 in a display device 2 according to a ninth embodiment of the disclosure.

As illustrated in FIG. 55, the light-emitting element layer 5 according to the ninth embodiment has the same configuration as the light-emitting element layer 5 according to the second embodiment described above except that no edge cover is provided.

As illustrated in FIG. 55, the light-emitting element layer 5 according to the ninth embodiment has the same configuration as the light-emitting element layer 5 according to the eighth embodiment described above except that a side surface of a green electron transport layer 33g is covered with a green light-emitting layer 35g, a side surface of a blue electron transport layer 33b is covered with a blue light-emitting layer 35b, and a side surface of a red electron transport layer 33r is covered with a red light-emitting layer 35r.

That is, the configuration according to the ninth embodiment is a configuration obtained by combining the configuration according to the second embodiment described above to the configuration according to the eighth embodiment described above. Thus, it is possible to further reduce the number of steps of the method for manufacturing the display device 2 according to the ninth embodiment as compared to the method for manufacturing the display device 2 according to the second embodiment described above.

Similarly to the method for manufacturing the display device 2 according to the second embodiment described above, according to the method for manufacturing the display device 2 according to the ninth embodiment, the resolution and/or yield of the display device 2 can be improved. It is possible to further improve the reliability of the display device 2. Furthermore, color gamut of the display device 2 can be improved. Furthermore, power consumption of the display device 2 can be reduced.

Note that an intermediate configuration between the configuration according to the eighth embodiment described above and the configuration according to the ninth embodiment is also included in the scope of the disclosure.

### Tenth Embodiment

### Configuration of Light-Emitting Element Layer

FIG. 56 is a cross-sectional view illustrating a schematic configuration of a light-emitting element layer 5 in a display device 2 according to a tenth embodiment of the disclosure.

As illustrated in FIG. 56, the light-emitting element layer 5 according to the tenth embodiment has the same configuration as the light-emitting element layer 5 according to the third embodiment described above except that no edge cover is provided.

As illustrated in FIG. 56, the light-emitting element layer 5 according to the tenth embodiment has the same configuration as the light-emitting element layer 5 according to the eighth embodiment described above except that end portions of a green electron transport layer 33g and a green light-emitting layer 35g overlap with end portions of a blue electron transport layer 33b and a blue light-emitting layer 35b, end portions of the green electron transport layer 33g and the green light-emitting layer 35g overlap with end portions of a red electron transport layer 33r and a red light-emitting layer 35r, and end portions of the red electron transport layer 33r and the red light-emitting layer 35r overlap with end portions of the blue electron transport layer 33b and the blue light-emitting layer 35b.

That is, the configuration according to the tenth embodiment is a configuration obtained by combining the configuration according to the third embodiment described above to the configuration according to the eighth embodiment described above. Thus, it is possible to further reduce the number of steps of the method for manufacturing the display device 2 according to the tenth embodiment as compared to the method for manufacturing the display device 2 according to the third embodiment described above.

Similarly to the method for manufacturing the display device 2 according to the third embodiment described above, according to the method for manufacturing the display device 2 according to the tenth embodiment, the resolution and/or yield of the display device 2 can be improved. It is possible to improve the reliability of the display device 2. Furthermore, color gamut of the display device 2 can be improved. Furthermore, power consumption of the display device 2 can be reduced.

Note that an intermediate configuration between the configuration according to the eighth embodiment described above and the configuration according to the tenth embodiment is also included in the scope of the disclosure.

### Forming Pattern of Light-Emitting Layer

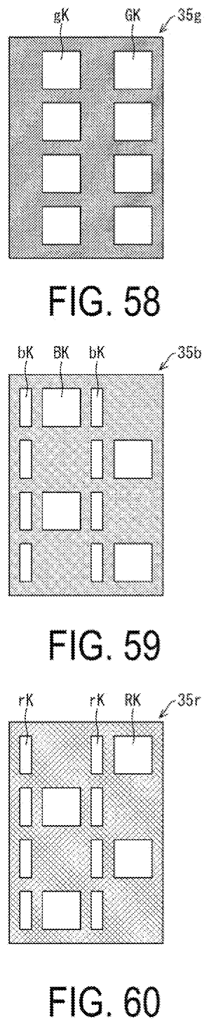

FIG. 57 is a plan view illustrating an example of an arrangement pattern of green pixel electrodes PEg, blue pixel electrodes PEb, and red pixel electrodes PEr. FIG. 58 is a plan view illustrating an example of a forming pattern of the green light-emitting layer 35g illustrated in FIG. 56 in a case of the arrangement pattern illustrated in FIG. 56. FIG. 59 is a plan view illustrating an example of a forming pattern of the blue light-emitting layer 35b illustrated in FIG. 56 in the case of the arrangement pattern illustrated in FIG. 56. FIG. 60 is a plan view illustrating an example of a forming pattern of the red light-emitting layer 35r illustrated in FIG. 56 in the case of the arrangement pattern illustrated in FIG. 56.

As illustrated in FIG. 56, the green light-emitting layer 35g according to the tenth embodiment is preferably a layer common to a plurality of adjacent green subpixels Pg (a plurality of adjacent subpixels of the same color). The green light-emitting layer 35g overlaps with the entire green pixel electrodes PEg. Preferably, the green light-emitting layer 35g includes openings GK overlapping with the blue pixel electrodes PEb and openings gK overlapping with the red pixel electrodes PEr, and is formed over the entire display region. As an example, in a case where the green pixel electrodes PEg, the blue pixel electrodes PEb, and the red pixel electrodes PEr are arranged in a PenTile manner as illustrated in FIG. 57, the green light-emitting layer 35g is preferably formed as illustrated in FIG. 58. The openings GK overlapping with the blue pixel electrodes PEb each are open to the inside of the perimeter edge portion of each of the blue pixel electrodes PEb, and the green light-emitting layer 35g overlaps with the entire circumference of the perimeter edge portion of each of the blue pixel electrodes PEb. The openings gK overlapping with the red pixel electrodes PEr each are open to the inside of the perimeter edge portion of each of the red pixel electrodes PEr, and the green light-emitting layer 35g overlaps with the entire circumference of the perimeter edge portion of each of the red pixel electrodes PEr.

Similarly, the blue light-emitting layer 35b according to the tenth embodiment is preferably a layer common to a plurality of adjacent blue subpixels Pb (a plurality of adjacent subpixels of the same color). The blue light-emitting layer 35b overlaps with the entire blue pixel electrodes PEb. The blue light-emitting layer 35b includes openings bk overlapping with the green pixel electrodes PEg and openings BK overlapping with the red pixel electrodes PEr, and is preferably formed over the entire display region. As an example, in a case where the green pixel electrodes PEg, the blue pixel electrodes PEb, and the red pixel electrodes PEr are arranged in the PenTile manner as illustrated in FIG. 57, the blue light-emitting layer 35b is preferably formed as illustrated in FIG. 59. The openings bk overlapping with the green pixel electrodes PEg each are open to the inside of the perimeter edge portion of each of the green pixel electrodes PEg, and the blue light-emitting layer 35b overlaps with the entire circumference of the perimeter edge portion of each of the green pixel electrodes PEg. The openings BK overlapping with the red pixel electrodes PEr each are open to the inside of the perimeter edge portion of each of the red pixel electrodes PEr, and the blue light-emitting layer 35b overlaps with the entire circumference of the perimeter edge portion of each of the red pixel electrodes PEr.

Similarly, the red light-emitting layer 35r according to the tenth embodiment is preferably a layer common to a plurality of adjacent red subpixels Pr (a plurality of adjacent subpixels of the same color). The red light-emitting layer 35r overlaps with the entire red pixel electrodes PEr. The red light-emitting layer 35r includes openings rk overlapping with the green pixel electrodes PEg and openings RK overlapping with the blue pixel electrodes PEb, and is preferably formed over the entire display region. As an example, in a case where the green pixel electrodes PEg, the blue pixel electrodes PEb, and the red pixel electrodes PEr are arranged in the Pen Tile manner as illustrated in FIG. 57, the red light-emitting layer 35r is preferably formed as illustrated in FIG. 60. The openings rk overlapping with the green pixel electrodes PEg each are open to the inside of the perimeter edge portion of each of the green pixel electrodes PEg, and the red light-emitting layer 35r overlaps with the entire circumference of the perimeter edge portion of each of the green pixel electrodes PEg. The openings RK overlapping with the blue pixel electrodes PEb each are open to the inside of the perimeter edge portion of each of the blue pixel electrodes PEb, and the red light-emitting layer 35r overlaps with the entire circumference of the perimeter edge portion of each of the blue pixel electrodes PEb.

As a result of these, the three light-emitting layers 35g, 35b, and 35r overlap with perimeter edge portions of the respective pixel electrodes PEr, PEg, and PEb and function as edge covers. Furthermore, such a forming pattern of the light-emitting layers can also be applied to the third and fourth embodiments described above and an eleventh embodiment described below.

### Eleventh Embodiment

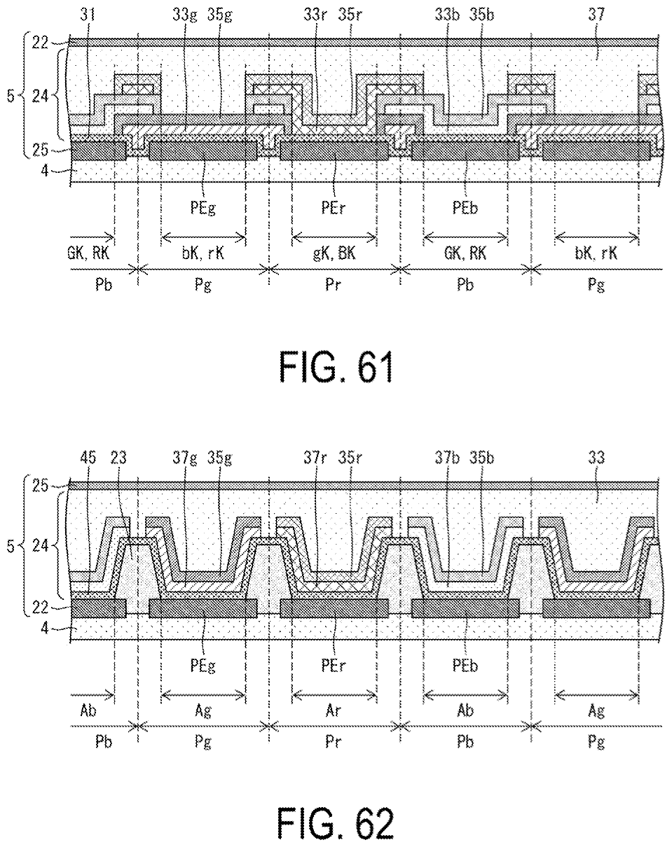

FIG. 61 is a cross-sectional view illustrating a schematic configuration of a light-emitting element layer 5 in a display device 2 according to an eleventh embodiment of the disclosure.

As illustrated in FIG. 61, the light-emitting element layer 5 according to the eleventh embodiment has the same configuration as the light-emitting element layer 5 according to the fourth embodiment described above except that no edge cover is provided.

As illustrated in FIG. 61, the light-emitting element layer 5 according to the eleventh embodiment has the same configuration as the light-emitting element layer 5 according to the tenth embodiment described above except that a side surface of a green electron transport layer 33g is covered with a green light-emitting layer 35g, a side surface of a blue electron transport layer 33b is covered with a blue light-emitting layer 35b, and a side surface of a red electron transport layer 33r is covered with a red light-emitting layer 35r.

That is, the configuration according to the eleventh embodiment is a configuration obtained by combining the configuration according to the fourth embodiment described above to the configuration according to the tenth embodiment described above. Thus, the configuration according to the eleventh embodiment is a configuration obtained by combining the configuration according to the third embodiment described above to the configuration according to the eighth embodiment described above and further combining the second embodiment described above. Thus, it is possible to further reduce the number of steps of the method for manufacturing the display device 2 according to the eleventh embodiment as compared to the method for manufacturing the display device 2 according to the fourth embodiment described above.

Similarly to the method for manufacturing the display device 2 according to the third embodiment described above, according to the method for manufacturing the display device 2 according to the eleventh embodiment, the resolution and/or yield of the display device 2 can be improved. It is possible to further improve the reliability of the display device 2. Furthermore, color gamut of the display device 2 can be improved. Furthermore, power consumption of the display device 2 can be reduced.

Note that an intermediate configuration of the configurations according to the eighth, ninth, and tenth embodiments and the configuration according to the eleventh embodiment is also included within the scope of the disclosure.

Similarly to the green light-emitting layer 35g according to the tenth embodiment, the green light-emitting layer 35g according to the eleventh embodiment includes openings GK overlapping with blue pixel electrodes PEb and openings gK overlapping with red pixel electrodes PEr, and is preferably formed over the entire display region.

Similarly to the blue light-emitting layer 35b according to the tenth embodiment, the blue light-emitting layer 35b according to the eleventh embodiment includes openings bk overlapping with green pixel electrodes PEg and openings BK overlapping with the red pixel electrodes PEr, and is preferably formed over the entire display region.

Similarly to the red light-emitting layer 35r according to the tenth embodiment, a red light-emitting layer 35b according to the eleventh embodiment includes openings rk overlapping with the green pixel electrodes PEg and openings RK overlapping with the blue pixel electrodes PEb, and is preferably formed over the entire display region.

### Twelfth Embodiment

FIG. 62 is a cross-sectional view illustrating a schematic configuration of a light-emitting element layer 5 in a display device 2 according to a twelfth embodiment of the disclosure.

As illustrated in FIG. 62, the light-emitting element layer 5 according to the present embodiment has the same configuration as the light-emitting element layer 5 according to the first embodiment described above except for the following three points. One point is that the layering order in an active layer 24 is inverted in such a manner that layering occurs in the order of an anode 22 to a cathode 25. Another point is that along with the inversion of the layering order, the active layer 24 includes (i) a hole injection layer 45 formed in a solid shape, (ii) a green hole transport layer 37g formed in an island shape in a green subpixel Pg, (iii) a blue hole transport layer 37b formed in an island shape in a blue subpixel Pb, (iv) a red hole transport layer 37r formed in an island shape in a red subpixel Pr, and (v) an electron transport layer 33 formed in a solid shape. Still another point is that along with the inversion of the layering order, the anode 22 is formed as a green pixel electrode PEg, a blue pixel electrode PEb, and a red pixel electrode PEr, and the cathode 25 is formed as a common electrode.

A green light-emitting layer 35g is in direct contact with the green hole transport layer 37g, and covers the entire upper surface of the green hole transport layer 37g.

The green hole transport layer 37g is composed of a hole transport material that can be etched using the etching solution 56 that does not erode the green light-emitting layer 35g (i.e., a cured green photosensitive resin 43g). The photosensitive resin after curing is often insoluble in an organic solvent such as toluene or chlorobenzene. Thus, the etching solution 56 is preferably an organic solvent in which the green photosensitive resin 43g is insoluble. In this case, the green hole transport layer 37g is composed of a light curable hole transport material soluble in an organic solvent in which the green photosensitive resin 43g is insoluble. Such a hole transport material is, for example, a polymer of a compound represented by Chemical Formula (1) below (so-called “OTPD”), and a polymer of a compound represented by Chemical Formula (2) below (so-called “DHTBOX”). For example, the polymer of DHTBOX is represented by Chemical Formula (3) below.

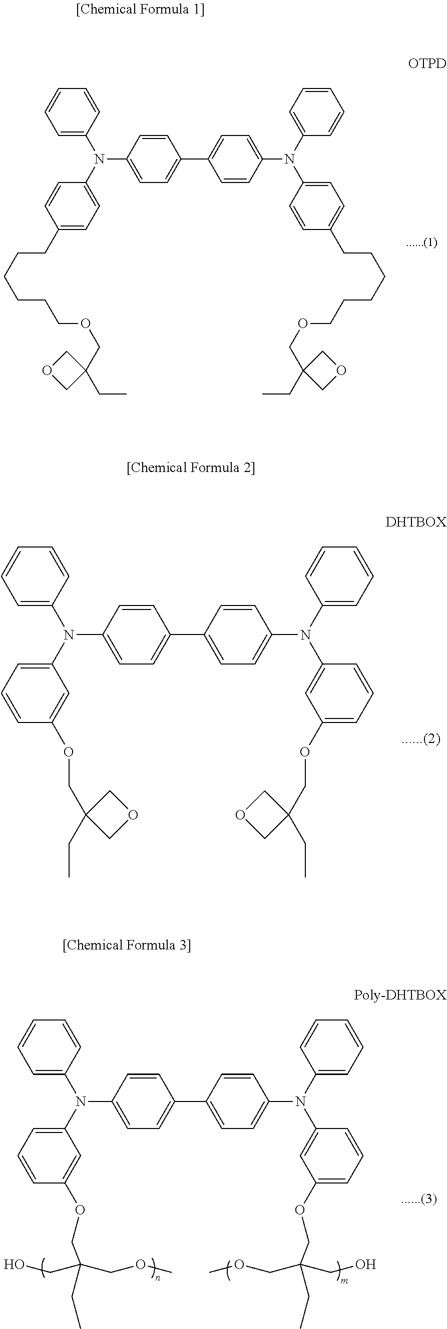

Monomers of OPTD and DHTBOX have an oxetanyl group that is a 4-membered cyclic ether group. As a result, the monomers of OPTD and DHTBOX are subjected to ring-opening polymerization by ultraviolet irradiation or heating, and cross-linked in three dimensions and cured to form a polymer. Thus, the method of curing a forming material of the green hole transport layer 37g may be exposure treatment, heat treatment, or both of the exposure treatment and the heat treatment. For example, the green hole transport layer 37g may be cured to be formed by the exposure treatment, a green coating liquid 34g may be applied, the green hole transport layer 37g may be etched, and then the green hole transport layer 37g may be additionally cured by the heat treatment. For example, the green hole transport layer 37g may be cured to be formed by the exposure treatment, the green hole transport layer 37g may be additionally cured by the heat treatment, and then the green coating liquid 34g may be applied. Furthermore, as necessary, for example, a diaryliodonium-based cation initiator as represented by Chemical Formula (4) below, for example, an anion initiator as represented by Chemical Formula (5) below, and a photopolymerization initiator such as a radical initiator may be added to the forming material of the green hole transport layer 37g.

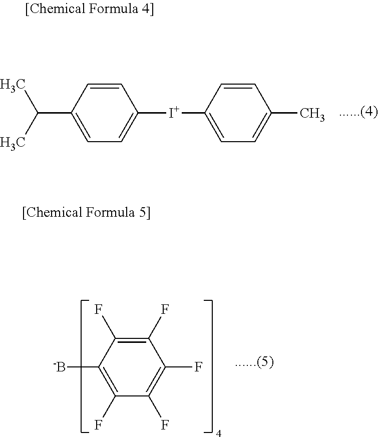

A blue light-emitting layer 35b is in direct contact with a blue hole transport layer 37b, and covers the entire upper surface of the blue hole transport layer 37b.

The blue hole transport layer 37b is composed of a hole transport material that can be etched using the etching solution 56 that does not erode the blue light-emitting layer 35b (i.e., a cured blue photosensitive resin 43b). The photosensitive resin after curing is often insoluble in an organic solvent such as toluene or chlorobenzene. Thus, the etching solution 56 is preferably an organic solvent in which the blue photosensitive resin 43b is insoluble. In this case, the blue hole transport layer 37b is composed of a light curable hole transport material soluble in an organic solvent in which the blue photosensitive resin 43b is insoluble. Such a hole transport material is, for example, a polymer of OTPD and DHTBOX.

The method of curing a forming material of the blue hole transport layer 37b may be exposure treatment, heat treatment, or both of the exposure treatment and the heat treatment. For example, the blue hole transport layer 37b may be cured to be formed by the exposure treatment, a blue coating liquid 34b may be applied, the blue hole transport layer 37b may be etched, and then the blue hole transport layer 37b may be additionally cured by the heat treatment. For example, the blue hole transport layer 37b may be cured to be formed by the exposure treatment, the blue hole transport layer 37b may be additionally cured by the heat treatment, and then the blue coating liquid 34b may be applied. Furthermore, as necessary, a photopolymerization initiator as described above may be added to the forming material of the blue hole transport layer 37b.

The red light-emitting layer 35r is in direct contact with the red hole transport layer 37r, and covers the entire upper surface of the red hole transport layer 37r.

The red hole transport layer 37r is composed of a hole transport material that can be etched using the etching solution 56 that does not erode the red light-emitting layer 35r (i.e., a cured red photosensitive resin 43r). The photosensitive resin after curing is often insoluble in an organic solvent such as toluene or chlorobenzene. Thus, the etching solution 56 is preferably an organic solvent in which the red photosensitive resin 43r is insoluble. In this case, the red hole transport layer 37r is composed of a light curable hole transport material soluble in an organic solvent in which the red photosensitive resin 43r is insoluble. Such a hole transport material is, for example, a polymer of OTPD and DHTBOX.

The method of curing a forming material of the red hole transport layer 37r may be exposure treatment, heat treatment, or both of the exposure treatment and the heat treatment. For example, the red hole transport layer 37r may be cured to be formed by curing due to the exposure treatment, a red coating liquid 34r may be applied, the red hole transport layer 37r may be etched, and then the red hole transport layer 37r may be additionally cured by the heat treatment. For example, the red hole transport layer 37r may be cured to be formed by the exposure treatment, the red hole transport layer 37r may be additionally cured by the heat treatment, and then the red coating liquid 34r may be applied. Further, the photopolymerization initiator as described above may be added to the forming material of the red hole transport layer 37r, as necessary.

The green hole transport layer 37g, the blue hole transport layer 37b, and the red hole transport layer 37r are separated from each other.

The electron transport layer 33 is formed in a solid shape so as to cover the green light-emitting layer 35g, the red light-emitting layer 35r, and the blue light-emitting layer 35b (if exposed, the exposed portion of the hole injection layer 45 and the exposed portion of the edge cover 23). This is not a limitation, and the electron transport layer 33 need not be formed, or may be formed separately in an island shape for each subpixel so as to individually cover the green light-emitting layer 35g, the red light-emitting layer 35r, and the blue light-emitting layer 35b, paired with the anode 22. Furthermore, the electron transport layer 33 may have a multilayer structure.

Thus, the method for manufacturing the display device 2 according to the twelfth embodiment can exhibit the same effects as those of the method for manufacturing the display device 2 according to the first embodiment described above.

Note that a configuration obtained by similarly inverting the layering order in the active layer 24 in the configurations of the display device 2 according to the second to eleventh embodiments is also within the scope of the disclosure.

### Supplement

A method for manufacturing a display device according to a first aspect of the disclosure is a method for manufacturing the display device including a substrate, a first subpixel including a first pixel electrode provided on the substrate, a first light-emitting layer first quantum dots, and a first charge transport layer provided between the first pixel electrode and the first light-emitting layer, and a second subpixel including a second pixel electrode provided on the substrate, the method including: forming the first charge transport layer on the first pixel electrode and the second pixel electrode; applying a first mixture obtained by mixing the first quantum dots and a photosensitive resin on the first charge transport layer; pattern-exposing the first mixture to cure a portion of the first mixture to be formed into the first light-emitting layer; removing an uncured portion of the first mixture; and etching the first charge transport layer with an etching solution using the first light-emitting layer as a mask, the etching solution being an alkaline solution or an organic solvent.

A method for manufacturing a display device according to a second aspect of the disclosure may be the method according to the first aspect in which in the etching of the first charge transport layer, the first charge transport layer is etched to remove a perimeter edge portion of a portion of the first charge transport layer, the portion being between the first light-emitting layer and the substrate.

A method for manufacturing a display device according to a third aspect of the disclosure may be the method according to the first aspect further including, before the forming of the first charge transport layer, forming a bank having insulating properties to cover a perimeter edge portion of the first pixel electrode, an angle formed between a side surface of the bank on the first pixel electrode side and a surface of the first pixel electrode being an acute angle.

A method for manufacturing a display device according to a fourth aspect of the disclosure may be the method according to any one of the first to third aspects in which the etching solution is an alkaline solution, and the removing of the first mixture and the etching of the first charge transport layer are performed in series in a single step or in parallel.

A method for manufacturing a display device according to a fifth aspect of the disclosure may be the method according to any one of the first to fourth aspects in which the second subpixel includes a second light-emitting layer including second quantum dots, and a second charge transport layer provided between the second pixel electrode and the second light-emitting layer and having the same polarity as the first charge transport layer, the method further including: forming the second charge transport layer on the first light-emitting layer and the second pixel electrode; applying a second mixture obtained by mixing the second quantum dots and a photosensitive resin on the second charge transport layer; pattern-exposing the second mixture to cure a portion of the second mixture to be formed into the second light-emitting layer; removing an uncured portion of the second mixture; and etching the second charge transport layer with the etching solution to expose at least partially the first light-emitting layer using the second light-emitting layer as a mask.

A display device according to a sixth aspect of the disclosure has a configuration including: a substrate; a first subpixel including a first pixel electrode provided on the substrate, a first light-emitting layer including first quantum dots, and a first charge transport layer provided between the first pixel electrode and the first light-emitting layer; a second subpixel including a second pixel electrode provided on the substrate, a second light-emitting layer having second quantum dots, and a second charge transport layer provided between the second pixel electrode and the second light-emitting layer and having the same polarity as the first charge transport layer, the second subpixel being adjacent to the first subpixel; and a third subpixel including a third pixel electrode provided on the substrate, a third light-emitting layer including third quantum dots, and a third charge transport layer provided between the third pixel electrode and the third light-emitting layer and having the same polarity as the first charge transport layer, the third subpixel being adjacent to the first subpixel, in which the first charge transport layer, the second charge transport layer, and the third charge transport layer are soluble in an etching solution which is an alkaline solution or an organic solvent, the first light-emitting layer is in direct contact with the first charge transport layer, the second light-emitting layer is in direct contact with the second charge transport layer, the third light-emitting layer is in direct contact with the third charge transport layer, each of the first light-emitting layer, the second light-emitting layer, and the third light-emitting layer includes a cured photosensitive resin that is insoluble in the etching solution, and the first charge transport layer, the second charge transport layer, and the third charge transport layer are separated from each other.

A display device according to a seventh aspect of the disclosure may be the display device according to the sixth aspect in which at least one light-emitting layer of the first light-emitting layer, the second light-emitting layer, and the third light-emitting layer covers at least a part of a side surface of a corresponding charge transport layer of the first charge transport layer, the second charge transport layer, and the third charge transport layer.

A display device according to an eighth aspect of the disclosure may be the display device according to the seventh aspect in which the first light-emitting layer covers at least a part of a side surface of the first charge transport layer, the second light-emitting layer covers at least a part of a side surface of the second charge transport layer, and the third light-emitting layer covers at least a part of a side surface of the third charge transport layer.

A display device according to a ninth aspect of the disclosure may be the display device according to any one of the sixth to eighth aspects further including: a common electrode provided on a side opposite to the first charge transport layer with respect to the first light-emitting layer, on a side opposite to the second charge transport layer with respect to the second light-emitting layer, and on a side opposite to the third charge transport layer with respect to the third light-emitting layer; and a fourth charge transport layer provided between the first light-emitting layer, the second light-emitting layer, and the third light-emitting layer, and the common electrode and having a reverse polarity to the first charge transport layer, in which one or both of the common electrode and the fourth charge transport layer are formed between the first light-emitting layer and the second light-emitting layer, and between the first light-emitting layer and the third light-emitting layer.

A display device according to a tenth aspect of the disclosure may be the display device according to any one of the sixth to eighth aspects further including a bank having insulating properties and formed to cover a perimeter edge portion of the first light-emitting layer.

A display device according to an eleventh aspect of the disclosure may be the display device according to any one of the sixth to eighth aspects in which the first light-emitting layer covers an entire side surface of the first charge transport layer, a portion of the second charge transport layer overlaps with a portion of the first charge transport layer with the first light-emitting layer interposed between the portion of the second charge transport layer and the portion of first charge transport layer, and a portion of the third charge transport layer overlaps with a portion of the first charge transport layer with the first light-emitting layer interposed between the portion of the third charge transport layer and the portion of the first charge transport layer.

A display device according to a twelfth aspect of the disclosure has a configuration including: a substrate; a first subpixel including a first pixel electrode provided on the substrate, a first light-emitting layer including first quantum dots, and a first charge transport layer provided between the first pixel electrode and the first light-emitting layer; a second subpixel including a second pixel electrode provided on the substrate, a second light-emitting layer including second quantum dots, and a second charge transport layer provided between the second pixel electrode and the second light-emitting layer and having the same polarity as the first charge transport layer, the second subpixel being adjacent to the first subpixel; and a third subpixel including a third pixel electrode provided on the substrate, a third light-emitting layer including third quantum dots, and a third charge transport layer provided between the third pixel electrode and the third light-emitting layer and having the same polarity as the first charge transport layer, the third subpixel being adjacent to the first subpixel, in which the first charge transport layer, the second charge transport layer, and the third charge transport layer are soluble in an etching solution that is an alkaline solution or an organic solvent, the first light-emitting layer is in direct contact with the first charge transport layer, the second light-emitting layer is in direct contact with the second charge transport layer, the third light-emitting layer is in direct contact with the third charge transport layer, each of the first light-emitting layer, the second light-emitting layer, and the third light-emitting layer includes a cured photosensitive resin that is insoluble in the etching solution, a portion of the second charge transport layer overlaps with a portion of the first charge transport layer with the first light-emitting layer interposed between the portion of the second charge transport layer and the portion of the first charge transport layer, and a portion of the third charge transport layer overlaps with a portion of the first charge transport layer with the first light-emitting layer interposed between the portion of the third charge transport layer and the portion of the first charge transport layer.

A display device according to a thirteenth aspect of the disclosure may be the display device according to the eleventh or twelfth aspect in which each of the first light-emitting layer, the second light-emitting layer, and the third light-emitting layer is a layer common to a plurality of adjacent subpixels of the same color, a portion of the third charge transport layer overlaps with a portion of the second charge transport layer with the second light-emitting layer interposed between the portion of the third charge transport layer and the portion of the second charge transport layer, the first light-emitting layer overlaps with the entire first pixel electrode, includes openings inside perimeter edge portions of a plurality of pixel electrodes included in the subpixels of the same color as the second subpixel and overlaps with entire circumferences of the perimeter edge portions, and includes openings inside perimeter edge portions of a plurality of pixel electrodes included in the subpixels of the same color as the third subpixel and overlaps with entire circumferences of the perimeter edge portions, the second light-emitting layer overlaps with the entire second pixel electrode, includes openings inside perimeter edge portions of a plurality of pixel electrodes included in the subpixels of the same color as the first subpixel and overlaps with entire circumferences of the perimeter edge portions, and includes openings inside perimeter edge portions of a plurality of pixel electrodes included in the subpixels of the same color as the third subpixel and overlaps with entire circumferences of the perimeter edge portions, and the third light-emitting layer includes an opening inside a perimeter edge portion of the first pixel electrode and overlaps with an entire circumference of the perimeter edge portion, includes openings inside perimeter edge portions of a plurality of pixel electrodes included in the subpixels of the same color as the first subpixel and overlaps with entire circumferences of the perimeter edge portions, and includes openings inside perimeter edge portions of a plurality of pixel electrodes included in the subpixels of the same color as the second subpixel and overlaps entire circumferences of the perimeter edge portions.

A display device according to a fourteenth aspect of the disclosure may be the display device according to any one of the sixth to eighth and tenth to thirteenth aspects, further including a bank having insulating properties and formed to cover a perimeter edge portion of the first pixel electrode, an angle formed between a side surface of the bank on the first pixel electrode side and a surface of the first pixel electrode being an acute angle.

A display device according to a fifteenth aspect of the disclosure may be the display device according to any one of the sixth to fourteenth aspects in which the first charge transport layer, the second charge transport layer, and the third charge transport layer are different from each other in a film thickness or material.

A display device according to a sixteenth aspect of the disclosure may be the display device according to any one of the sixth to fifteenth aspects in which the etching solution is an alkaline solution.

A display device according to a seventeenth aspect of the disclosure has a configuration including: a substrate; a first subpixel including a first pixel electrode provided on the substrate, a first light-emitting layer including first quantum dots, and a first portion of a charge transport layer provided between the first pixel electrode and the first light-emitting layer; a second subpixel including a second pixel electrode provided on the substrate, a second light-emitting layer including second quantum dots, and a second portion of the charge transport layer provided between the second pixel electrode and the first light-emitting layer, the second subpixel being adjacent to the first subpixel; and a third subpixel including a third pixel electrode provided on the substrate, a third light-emitting layer including third quantum dots, and a third portion of the charge transport layer provided between the third pixel electrode and the third light-emitting layer, the third subpixel being adjacent to the first subpixel, in which the charge transport layer is soluble in an etching solution that is an alkaline solution or an organic solvent, the first light-emitting layer is in direct contact with the first portion of the charge transport layer, and includes a cured photosensitive resin that is insoluble in the etching solution, and each of the second portion and the third portion of the charge transport layer is thinner than the first portion of the charge transport layer.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1.-5. (canceled)

6. A display device comprising:
a substrate;
a first subpixel including a first pixel electrode provided on the substrate, a first light-emitting layer including first quantum dots, and a first charge transport layer provided between the first pixel electrode and the first light-emitting layer;
a second subpixel including a second pixel electrode provided on the substrate, a second light-emitting layer including second quantum dots, and a second charge transport layer provided between the second pixel electrode and the second light-emitting layer and having the same polarity as the first charge transport layer, the second subpixel being adjacent to the first subpixel; and
a third subpixel including a third pixel electrode provided on the substrate, a third light-emitting layer including third quantum dots, and a third charge transport layer provided between the third pixel electrode and the third light-emitting layer and having the same polarity as the first charge transport layer, the third subpixel being adjacent to the first subpixel,
wherein the first charge transport layer, the second charge transport layer, and the third charge transport layer are soluble in an etching solution which is an alkaline solution or an organic solvent,
the first light-emitting layer is in direct contact with the first charge transport layer,
the second light-emitting layer is in direct contact with the second charge transport layer,
the third light-emitting layer is in direct contact with the third charge transport layer,
each of the first light-emitting layer, the second light-emitting layer, and the third light-emitting layer includes a cured photosensitive resin that is insoluble in the etching solution, and
the first charge transport layer, the second charge transport layer, and the third charge transport layer are separated from each other.

7. The display device according to claim 6,
wherein at least one light-emitting layer of the first light-emitting layer, the second light-emitting layer, and the third light-emitting layer covers at least a part of a side surface of a corresponding charge transport layer of the first charge transport layer, the second charge transport layer, and the third charge transport layer.

8. The display device according to claim 7,
wherein the first light-emitting layer covers at least a part of a side surface of the first charge transport layer,
the second light-emitting layer covers at least a part of a side surface of the second charge transport layer, and
the third light-emitting layer covers at least a part of a side surface of the third charge transport layer.

9. The display device according to claim 6, further comprising:
a common electrode provided on a side opposite to the first charge transport layer with respect to the first light-emitting layer, on a side opposite to the second charge transport layer with respect to the second light-emitting layer, and on a side opposite to the third charge transport layer with respect to the third light-emitting layer; and
a fourth charge transport layer provided between the first light-emitting layer, the second light-emitting layer, and the third light-emitting layer, and the common electrode and having a reverse polarity to the first charge transport layer,
wherein one or both of the common electrode and the fourth charge transport layer are formed between the first light-emitting layer and the second light-emitting layer, and between the first light-emitting layer and the third light-emitting layer.

10. The display device according to claim 6, further comprising a bank having an insulating property and formed to cover a perimeter edge portion of the first light-emitting layer.

11. The display device according to claim 6,
wherein the first light-emitting layer covers an entire side surface of the first charge transport layer,
a portion of the second charge transport layer overlaps with a portion of the first charge transport layer with the first light-emitting layer interposed between the portion of the second charge transport layer and the portion of first charge transport layer, and
a portion of the third charge transport layer overlaps with a portion of the first charge transport layer with the first light-emitting layer interposed between the portion of the third charge transport layer and the portion of the first charge transport layer.

12. A display device comprising:
a substrate;
a first subpixel including a first pixel electrode provided on the substrate, a first light-emitting layer including first quantum dots, and a first charge transport layer provided between the first pixel electrode and the first light-emitting layer;
a second subpixel including a second pixel electrode provided on the substrate, a second light-emitting layer including second quantum dots, and a second charge transport layer provided between the second pixel electrode and the second light-emitting layer and having the same polarity as the first charge transport layer, the second subpixel being adjacent to the first subpixel; and
a third subpixel including a third pixel electrode provided on the substrate, a third light-emitting layer including third quantum dots, and a third charge transport layer provided between the third pixel electrode and the third light-emitting layer and having the same polarity as the first charge transport layer, the third subpixel being adjacent to the first subpixel,
wherein the first charge transport layer, the second charge transport layer, and the third charge transport layer are soluble in an etching solution that is an alkaline solution or an organic solvent,
the first light-emitting layer is in direct contact with the first charge transport layer,
the second light-emitting layer is in direct contact with the second charge transport layer,
the third light-emitting layer is in direct contact with the third charge transport layer,
each of the first light-emitting layer, the second light-emitting layer, and the third light-emitting layer includes a cured photosensitive resin that is insoluble in the etching solution,
a portion of the second charge transport layer overlaps with a portion of the first charge transport layer with the first light-emitting layer interposed between the portion of the second charge transport layer and the portion of the first charge transport layer, and
a portion of the third charge transport layer overlaps with a portion of the first charge transport layer with the first light-emitting layer interposed between the portion of the third charge transport layer and the portion of the first charge transport layer.

13. The display device according to claim 11,
wherein each of the first light-emitting layer, the second light-emitting layer, and the third light-emitting layer is a layer common to a plurality of adjacent subpixels of the same color,
a portion of the third charge transport layer overlaps with a portion of the second charge transport layer with the second light-emitting layer interposed between the portion of the third charge transport layer and the portion of the second charge transport layer,
the first light-emitting layer overlaps with the entire first pixel electrode, includes openings inside perimeter edge portions of a plurality of pixel electrodes included in the subpixels of the same color as the second subpixel and overlaps with entire circumferences of the perimeter edge portions, and includes openings inside perimeter edge portions of a plurality of pixel electrodes included in the subpixels of the same color as the third subpixel and overlaps with entire circumferences of the perimeter edge portions,
the second light-emitting layer overlaps with the entire second pixel electrode, includes openings inside perimeter edge portions of a plurality of pixel electrodes included in the subpixels of the same color as the first subpixel and overlaps with entire circumferences of the perimeter edge portions, and includes openings inside perimeter edge portions of a plurality of pixel electrodes included in the subpixels of the same color as the third subpixel and overlaps with entire circumferences of the perimeter edge portions, and
the third light-emitting layer includes an opening inside a perimeter edge portion of the first pixel electrode and overlaps with an entire circumference of the perimeter edge portion, includes openings inside perimeter edge portions of a plurality of pixel electrodes included in the subpixels of the same color as the first subpixel and overlaps with entire circumferences of the perimeter edge portions, and includes openings inside perimeter edge portions of a plurality of pixel electrodes included in the subpixels of the same color as the second subpixel and overlaps entire circumferences of the perimeter edge portions.

14. The display device according to claim 6, further comprising a bank having an insulating property and formed to cover a perimeter edge portion of the first pixel electrode, an angle formed between a side surface of the bank on the first pixel electrode side and a surface of the first pixel electrode being an acute angle.

15. The display device according to claim 6,
wherein the first charge transport layer, the second charge transport layer, and the third charge transport layer are different from each other in a film thickness or material.

16. The display device according to claim 6,
wherein the etching solution is an alkaline solution.

17. A display device comprising:
a substrate;
a first subpixel including a first pixel electrode provided on the substrate, a first light-emitting layer including first quantum dots, and a first portion of a charge transport layer provided between the first pixel electrode and the first light-emitting layer;
a second subpixel including a second pixel electrode provided on the substrate, a second light-emitting layer including second quantum dots, and a second portion of the charge transport layer provided between the second pixel electrode and the second light-emitting layer, the second subpixel being adjacent to the first subpixel; and
a third subpixel including a third pixel electrode provided on the substrate, a third light-emitting layer including third quantum dots, and a third portion of the charge transport layer provided between the third pixel electrode and the third light-emitting layer, the third subpixel being adjacent to the first subpixel,
wherein the charge transport layer is soluble in an etching solution that is an alkaline solution or an organic solvent,
the first light-emitting layer
is in direct contact with the first portion of the charge transport layer, and
includes a cured photosensitive resin that is insoluble in the etching solution, and
each of the second portion and the third portion of the charge transport layer is thinner than the first portion of the charge transport layer.
